(19) United States
(12) Patent Application Publication
(10) Pub. No.: US 2025/0279369 A1
(43) Pub. Date: Sep. 4, 2025

(54) CIRCUIT BOARD

(71) Applicant: LG INNOTEK CO., LTD., Seoul (KR)

(72) Inventors: Kee Han LEE, Seoul (KR); Sang II KIM, Seoul (KR); Se Woong NA, Seoul (KR)

(21) Appl. No.: 18/580,286

(22) PCT Filed: Jul. 22, 2022
(86) PCT No.: PCT/KR2022/010820

§ 371 Date: Jul. 9, 2024

(30) Foreign Application Priority Data
Jul. 22, 2021 (KR) 10-2021-0096679

(51) Int. Cl. H01L 23/538; H01L 23/00; H01L 23/31; H01L 25/07

(52) U.S. Cl. CPC H01L 23/5386; H01L 23/3107; H01L 23/5383; H01L 23/564; H01L 25/072

(57) ABSTRACT

A circuit board according to an embodiment includes a first insulating layer; a first circuit pattern layer disposed on the first insulating layer; and a first protective layer disposed on the first insulating layer and the first circuit pattern layer, wherein the first circuit pattern layer includes a first pad, wherein the first protective layer is divided into a first portion disposed on the first insulating layer in a thickness direction and a second portion disposed on the first portion, wherein the second portion of the first protective layer includes an opening with a width greater than a width of the first pad, and wherein a side wall of the second portion forming the opening is provided with a recess portion recessed in an inward direction.

### TECHNICAL FIELD

The embodiment relates to a circuit board and a package substrate including the same.

### BACKGROUND ART

Generally, a printed circuit board (PCB) is a laminated structure in which insulating layers and conductor layers are alternately laminated, and the conductor layers may be provided with a circuit pattern by patterning.

Such printed circuit board includes a solder resist SR that protects the circuit pattern formed on an outermost side of the laminate structure, prevents oxidation of the conductor layer, and serves as an insulator when electrically connected to a chip mounted on a printed circuit board or another board.

A typical solder resist includes an opening region (SRO: Solder Resist Opening) where connection means such as solder or bumps are combined to form an electrical connection path. The opening region of the solder resist is required as the I/O (Input/Output) performance improves as the high performance and density of printed circuit boards increase, thereby a small bump pitch of the opening region is required. At this time, the bump pitch of the opening region refers to a center distance between adjacent opening regions.

Meanwhile, the opening region SRO of the solder resist includes a Solder Mask Defined (SMD) type and a Non-Solder Mask Defined (NSMD) type.

The SMD type is characterized in that a width of the opening region SRO is smaller than a width of the pad exposed through the opening region SRO, and accordingly, in the SMD type, at least a portion of an upper surface of the pad is covered by the solder resist.

In addition, the NSMD type is characterized in that a width of the opening region SRO is larger than a width of the pad exposed through the opening region SRO, and accordingly, the solder resist in the NSMD type is spaced apart from the pad at a certain interval and has a structure in which both the upper and side surfaces of the pad are exposed.

However, in the case of the above SMD type, when testing the solder ball joint reliability of a bonding strength of the solder ball after a semiconductor package is connected to a main board, there is a problem in that the solder ball is separated from the pad exposed through the opening region SRO. Additionally, in the case of the NSMD type, there is a problem in that the pad on which the solder ball is disposed is separated from the circuit board. Accordingly, conventionally, an appropriate combination of SMD type and NSMD type is applied to one circuit board.

However, when performing a process of exposing the solder resist layer in a case of the circuit board including conventional SMD type and NSMD type opening regions SRO, there is a problem in that light is not sufficiently transmitted to a lower region of an exposure region of the solder resist layer, and accordingly, the lower region of the exposure region is not sufficiently cured. In addition, if a development process is performed in a state where the lower region of the exposure region is not sufficiently cured, there is a problem that undercut occurs in which the lower region of the exposure region is removed. Furthermore, a width of the undercut becomes greater as a thickness of the solder resist layer increases, which reduces the reliability of the circuit board.

### DISCLOSURE

### Technical Problem

An embodiment provides a circuit board that can minimize a horizontal distance of a recess portion corresponding to an undercut in an open region of solder resist and a package substrate including the same.

Additionally, the embodiment provides a circuit board capable of reducing a width of a solder resist disposed between a plurality of circuit patterns and a package substrate including the same.

Additionally, the embodiment provides a circuit board capable of reducing a distance between circuit patterns disposed at an uppermost side of the circuit board and a package substrate including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises a first insulating layer; a first circuit pattern layer disposed on the first insulating layer; and a first protective layer disposed on the first insulating layer and the first circuit pattern layer, wherein the first circuit pattern layer includes a first pad, wherein the first protective layer is divided into a first portion disposed on the first insulating layer in a thickness direction and a second portion disposed on the first portion, and wherein the second portion of the first protective layer includes an opening with a width greater than a width of the first pad, and wherein a side wall of the second portion forming the opening is provided with a recess portion recessed in an inward direction.

In addition, a horizontal distance from an outermost end of the side wall of the second portion to an innermost end of the recess portion is 13 μm or less.

In addition, a thickness of the first portion of the first protective layer is smaller than a thickness of the first pad.

In addition, the thickness of the first portion of the first protective layer satisfies a range of 40% to 98% of the thickness of the first pad.

In addition, the recess portion is provided at a step portion between an upper surface of the first portion exposed through the opening and a side wall of the opening of the second portion connected to the upper surface of the first portion.

In addition, an upper surface of the first portion of the first protective layer is positioned lower than an upper surface of the first pad, and wherein an upper surface of the second portion of the first protective layer is positioned higher than the upper surface of the first pad.

In addition, the first circuit pattern layer includes a trace disposed adjacent to the first pad and covered by the second portion of the first protective layer; and wherein a shortest horizontal distance between a side surface of the trace and an outermost end of the side wall of the second portion satisfies a range of 1 um to 30 um.

Meanwhile, a circuit board according to the embodiment comprises a first insulating layer; a first circuit pattern layer disposed on the first insulating layer; and a first protective layer disposed on the first insulating layer and the first circuit pattern layer, wherein the first circuit pattern layer includes a first pad and an adjacent pattern adjacent to the first pad, wherein the first protective layer includes a first portion of a first region disposed between the first pad and the adjacent pattern and a second portion of the first region disposed on the first portion of the first region to cover the adjacent pattern and having a first opening exposing a portion of an upper surface of the first portion of the first region and the upper surface of the first pad, and wherein the second portion of the first region includes a first side wall corresponding to the first opening, and wherein a shortest horizontal distance between a side surface of the adjacent pattern and the first sidewall is 30 μm or less.

In addition, the adjacent pattern is a trace disposed adjacent to the first pad.

In addition, a recess portion recessed in the inward direction is provided at the first side wall of the second portion, and wherein a horizontal distance from an outermost end of the first side wall of the second portion to an innermost end of the recess portion is 13 μm or less.

In addition, the adjacent pattern is a third pad disposed adjacent to the first pad.

In addition, the second portion further includes a second opening exposing a portion of an upper surface of the third pad.

In addition, a first recess portion recessed in the inward direction is provided at the first side wall of the second portion.

In addition, the second portion includes a second side wall corresponding to the second opening, and a second recess portion recessed in an inner direction is provided at the side wall of the second portion.

In addition, the second portion includes a second opening exposing a portion of an upper surface of the third pad, wherein a first recess portion recessed in an inward direction is provided at the first side wall of the second portion, a second portion includes a second side wall corresponding to the second opening, and a second recess portion recessed in an inward direction is provided at the second side wall of the second portion, and wherein a horizontal distance from an innermost end of the first recess portion to an outermost end of the first side wall is greater than a horizontal distance from an innermost end of the second recess portion to an outermost end of the second side wall.

In addition, the horizontal distance from the innermost end of the first recess portion to the outermost end of the first side wall is 13 μm or less.

In addition, the first circuit pattern layer includes a second-first pad and a second-second pad, and the first protective layer includes a first portion of a second region disposed in a region in which the first circuit pattern layer is not disposed among regions between the second-first pad and the second-second pad, and a second portion of the second region disposed on the first portion of the second region and exposing a portion of an upper surface of the first portion of the second region, and wherein a width of the second portion of the second region is 40 um or less.

In addition, the thickness of the first portion of the first region satisfies a range of 40% to 98% of a thickness of the first pad.

Meanwhile, a package substrate according to the embodiment includes a circuit board, a connection part disposed on the first circuit pattern layer of the circuit board; a chip mounted on the connection part; and a molding layer for molding the chip, wherein at least one of the connection part and the molding layer is disposed in at least one recess portion formed on the circuit board.

In addition, the chip includes a first chip and a second chip that are spaced apart from each other in a width direction or arranged in a vertical direction.

### Advantageous Effects

A circuit board according to an embodiment includes a first protective layer. The first protective layer includes a first portion and a second portion having steps. And, in an embodiment, an opening formed in the first protective layer may be formed by selectively removing only the second portion excluding the first portion. At this time, a thickness of the first portion of the first protective layer is smaller than a thickness of the first circuit pattern layer exposed through the opening. Accordingly, the opening formed in the second portion of the first protective layer may expose a portion of a side surface of the first circuit pattern layer and an upper surface of the first circuit pattern layer. Accordingly, the embodiment allows the opening to have a depth corresponding to the thickness of the second portion rather than a depth corresponding to an entire thickness of the first protective layer. Accordingly, the embodiment can allow to significantly reduce a horizontal distance of a recess portion corresponding to an undercut formed at the side wall of the opening compared to the comparative example. Accordingly, the embodiment can reduce the horizontal distance of the recess portion, thereby improving the electrical reliability or physical reliability of the circuit board. For example, when the horizontal distance of the recess portion increases, a portion of the solder ball may penetrate between the recess portions, and short circuit problems may occur as neighboring circuit patterns are connected. For example, when the horizontal distance of the recess portion increases, an contact area between the first protective layer and the insulating layer decreases, and an adhesion force between the first protective layer and the insulating layer may be reduced. In contrast, the embodiment can reduce the horizontal distance of the recess portion, and accordingly, electrical reliability problems such as the short circuit can be solved, and furthermore, physical reliability problems such as the decrease in bonding force can be solved.

In addition, the embodiment allows the thickness of the first portion of the first protective layer to range from 40% to 98% of the first circuit pattern layer. Accordingly, the embodiment can dramatically reduce the horizontal distance of the recess portion while allowing the upper surface of the first circuit pattern layer to be stably exposed through an opening formed in the second portion.

In addition, the embodiment may reduce the horizontal distance of the recess portion to reduce a spacing between pads of the first circuit pattern layer, between a pad and a trace, or between traces. Specifically, the spacing between pads of the first circuit pattern layer or between a pad and a trace or between traces is determined by reflecting the horizontal distance of the recess portion to solve the electrical reliability problem. At this time, the embodiment may reduce the horizontal distance of the recess portion, and accordingly, the distance between the pads of the first circuit pattern layer, or between the pad and the trace, or between the traces, which is determined by the horizontal distance of the recess portion, can be dramatically reduced.

### DESCRIPTION OF DRAWINGS

FIG. 1a is a view showing a circuit board according to a comparative example.

FIG. 1b is an enlarged view of a first region of a first protective layer of FIG. 1a.

FIG. 1c is a view for explaining a defect in a first region of a first protective layer of FIG. 1b.

FIG. 1d is an enlarged view of a second region of a first protective layer of FIG. 1a.

FIG. 1e is a view for explaining a defect in a second region of a first protective layer of FIG. 1d.

FIG. 2a is a cross-sectional view of a circuit board according to an embodiment.

FIG. 2b is a plan view of the circuit board of FIG. 2a viewed from an top.

FIG. 3a is a view for explaining a process of exposing and curing a solder resist layer according to an embodiment.

FIG. 3b is a view for explaining a horizontal distance of a recess portion according to a thickness of a solder resist layer.

FIG. 3c is a view for explaining a horizontal distance of a recess portion according to a development depth of a solder resist layer.

FIG. 4a is a view showing results of an experiment on a horizontal distance of a recess portion in a solder resist layer made of a first insulating material.

FIG. 4b is a view for explaining results of an experiment on a horizontal distance of a recess portion in a solder resist layer made of a second insulating material different from the first insulating material.

FIG. 5a is a view showing a first-first region of a first region of a first protective layer of FIG. 2a.

FIG. 5b is a view showing a SAM photograph of a circuit board corresponding to FIG. 5a.

FIG. 6a is a view showing a first-second region of a first region of a first protective layer of FIG. 2a.

FIG. 6b is a view showing a SAM photograph of a circuit board corresponding to FIG. 6a.

FIG. 7a is a view showing a second region of a first protective layer of FIG. 2a.

FIG. 7b is a view showing a SAM photograph of a circuit board corresponding to FIG. 7a.

FIGS. 8a to 8j are diagrams for explaining a method for manufacturing a circuit board of FIG. 2a in order of process.

FIG. 9 is a view showing a package substrate according to a first embodiment.

FIG. 10 is a view showing the package substrate according to a second embodiment.

### MODES OF THE INVENTION

Hereinafter, the embodiment disclosed in the present specification will be described in detail with reference to the accompanying drawings, but the same or similar components are designated by the same reference numerals regardless of drawing numbers, and repeated description thereof will be omitted. The component suffixes “module” and “part” used in the following description are given or mixed together only considering the ease of creating the specification, and have no meanings or roles that are distinguished from each other by themselves. In addition, in describing the embodiments disclosed in the present specification, when it is determined that detailed descriptions of a related well-known art unnecessarily obscure gist of the embodiments disclosed in the present specification, the detailed description thereof will be omitted. Further, the accompanying drawings are merely for facilitating understanding of the embodiments disclosed in the present specification, the technological scope disclosed in the present specification is not limited by the accompanying drawings, and it should be understood as including all modifications, equivalents and alternatives that fall within the spirit and scope of the present invention.

It will be understood that, although the terms “first,” “second,” etc. may be used herein to describe various elements, these elements should not be limited by these terms. These terms are only used to distinguish one element from another.

It will be understood that when an element is referred to as being “connected” or “coupled” to another element, it can be directly connected or coupled to the other element or intervening elements may be present. In contrast, when an element is referred to as being “directly connected” or “directly coupled” to another element, it will be understood that there are no intervening elements present.

As used herein, a singular expression includes a plural expression, unless the context clearly indicates otherwise.

It will be understood that the terms “comprise”, “include”, or “have” specify the presence of stated features, integers, steps, operations, elements, components and/or groups thereof disclosed in the present specification, but do not preclude the possibility of the presence or addition of one or more other features, integers, steps, operations, elements, components, and/or groups thereof.

Hereinafter, embodiments of the present invention will be described in detail with reference to the accompanying drawings.

### Comparative Example

Before describing the embodiment, a comparative example compared to the circuit board of the embodiment of the present application will be described.

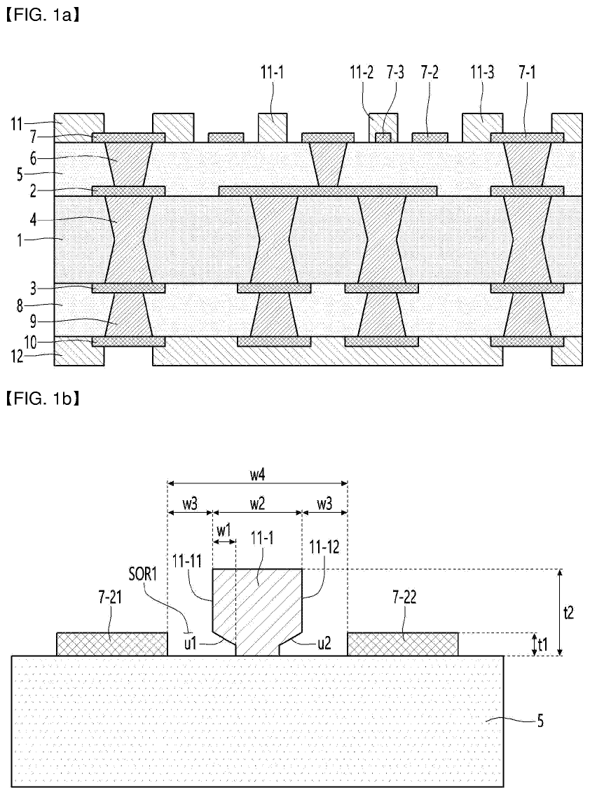

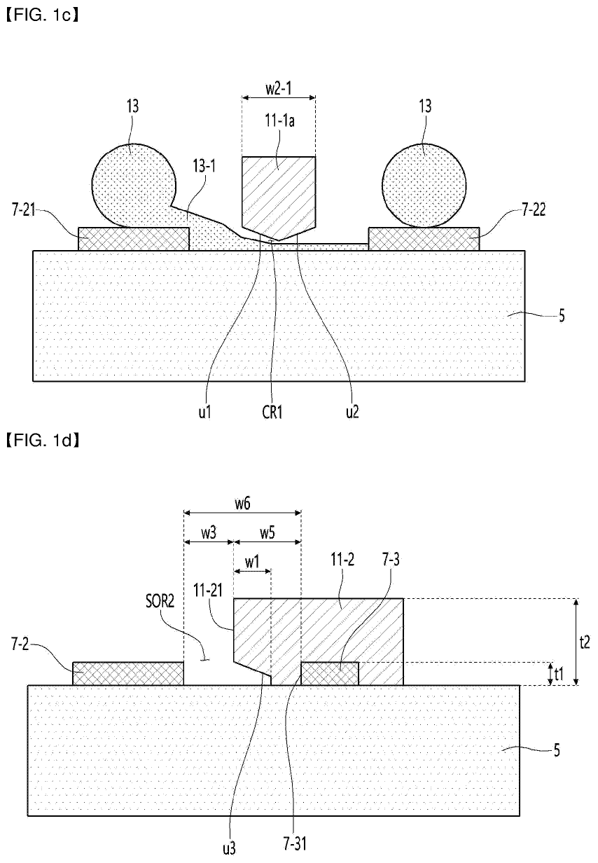

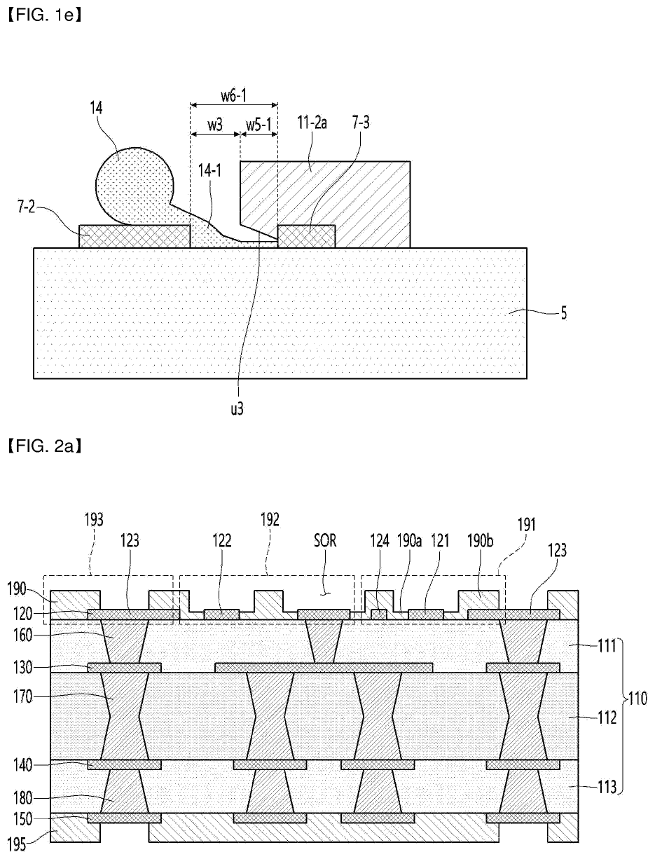

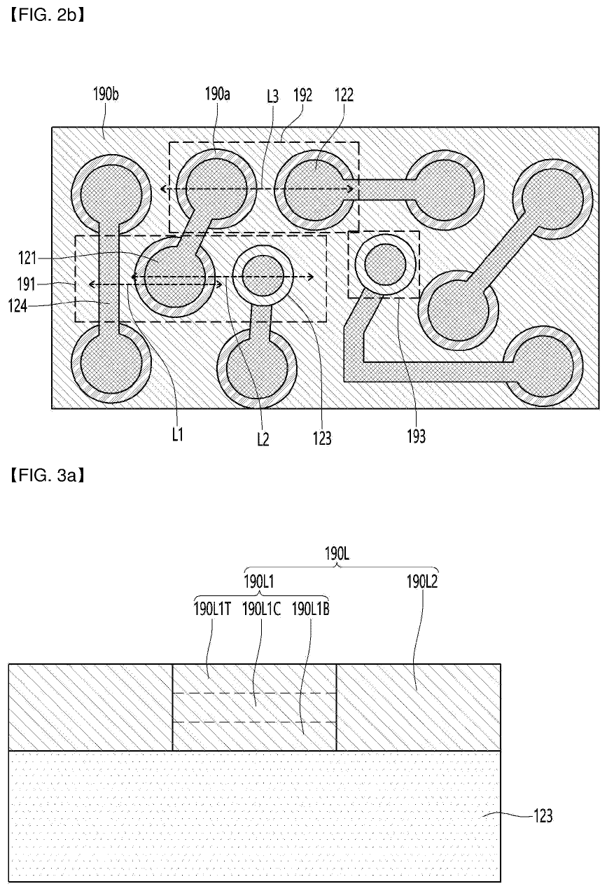

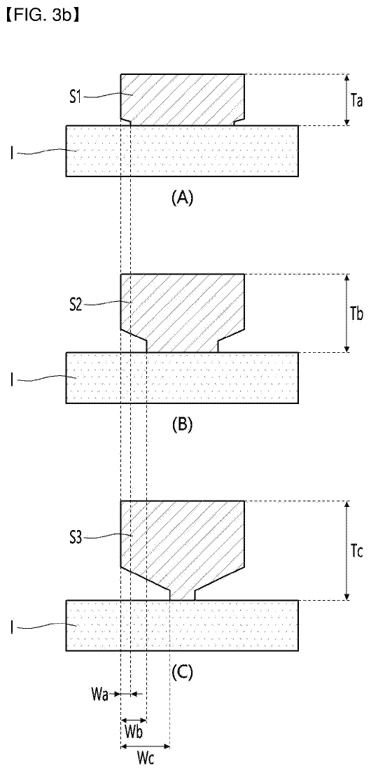

FIG. 1a is a view showing a circuit board according to a comparative example, FIG. 1b is an enlarged view of a first region of a first protective layer of FIG. 1a, FIG. 1c is a view for explaining a defect in a first region of a first protective layer of FIG. 1b, FIG. 1d is an enlarged view of a second region of a first protective layer of FIG. 1a, and FIG. 1e is a view for explaining a defect in a second region of a first protective layer of FIG. 1d.

Referring to FIG. 1a, the circuit board according to the comparative example includes an insulating layer, a circuit pattern, a via, and a protective layer.

The insulating layer includes a core layer 1, a first insulating layer 5, and a second insulating layer 8. In the circuit board of the comparative example, a first insulating layer 5 and a second insulating layer 8 are arranged in a symmetrical structure on upper and lower of the core layer 1. The core layer 1 is CCL (Clad Copper Laminate) containing prepreg, or contains materials such as silicon, glass, and ceramic used in an interposer.

The first insulating layer 5 and the second insulating layer 8 are disposed on the upper and lower surfaces of the core layer 1, respectively. The first insulating layer 5 and the second insulating layer 8 include a prepreg. For example, the first insulating layer 5 and the second insulating layer 8 include a resin and reinforcing fibers provided in the resin.

The first circuit pattern 2 is disposed on a lower surface of the first insulating layer 5. Additionally, the first circuit pattern 2 is disposed on an upper surface of the core layer 1. The first circuit pattern 2 is disposed to protrude on the upper surface of the core layer 1, and thus side and upper surfaces are covered by the first insulating layer 5.

The second circuit pattern 7 is disposed on an upper surface of the first insulating layer 5. The second circuit pattern 7 is disposed to protrude on the upper surface of the first insulating layer 5.

The third circuit pattern 3 is disposed on an upper surface of the second insulating layer 8. In addition, the third circuit pattern 3 is disposed on the lower surface of the second insulating layer 8.

The fourth circuit pattern 10 is disposed on a lower surface of the second insulating layer 8. The fourth circuit pattern 10 is disposed to protrude under the lower surface of the second insulating layer 8.

At this time, in a multilayer structure of the circuit board of the comparative example, the first insulating layer 5 is an insulating layer disposed on a first outermost or uppermost side, and the second insulating layer 8 is an insulating layer disposed on second outermost or lowermost side.

The first circuit pattern 2, the second circuit pattern 7, the third circuit pattern 3, and the fourth circuit pattern 10 each include pads and traces. The pad is a part where a via is connected, a chip is mounted, or an adhesive part (not shown) connected to the main board of an external substrate is disposed. The trace is a signal line that extends long from the pad.

The Via is disposed passing through each insulating layer. For example, the first via 6 is disposed to pass through the first insulating layer 5. One end of the first via 6 is connected to the first circuit pattern 2, and the other end is connected to the second circuit pattern 7. For example, the second via 4 is disposed to pass through the core layer 1. For example, the third via 9 is disposed to pass through the second insulating layer 8. For example, one end of the third via 9 is connected to the third circuit pattern 3 and the other end is connected to the fourth circuit pattern 10.

The first protective layer 11 and the second protective layer 12 are disposed on the upper surface of the first insulating layer 5 and the lower surface of the second insulating layer 8, respectively. The first protective layer 11 and the second protective layer 12 have openings that expose the surfaces of the second circuit pattern 7 and the fourth circuit pattern 1, respectively. The first protective layer 11 and the second protective layer 12 are a solder resist.

At this time, in the circuit board of the comparative example, one of the first and second outermost circuit patterns includes a mounting portion on which a chip is mounted, and the other includes a terminal portion connected to the main board of the external substrate.

For example, in the comparative example, the second circuit pattern 7 disposed on the first outermost side includes a mounting pad on which a chip is mounted, and the fourth circuit pattern 10 disposed on the second outermost side includes a terminal pad to which the main board of an external substrate is connected.

For example, the second circuit pattern 7 includes a plurality of pads and traces. The plurality of pads may be mounting pads on which chips are mounted, or may be core pads connected to a separate upper substrate. Specifically, the second circuit pattern 7 includes a first pad 7-1, a second pad 7-2, and a trace 7-3.

And, the first protective layer 11 is disposed on the upper surface of the first insulating layer 5 to cover the upper surface of the trace 7-3 of the second circuit pattern 7. And, the first protective layer 11 has an opening that exposes the upper surfaces of the first pad 7-1 and the second pad 7-2 of the second circuit pattern 7.

At this time, the first protective layer 11 may be divided into a plurality of regions depending on an arrangement position.

Referring to FIG. 1b, the first protective layer 11 includes a first region 11-1.

For example, the first protective layer 11 includes a first region 11-1 disposed between the second-first pad 7-21 and the second-second pad 7-22. And, the first region 11-1 of the first protective layer 11 is a region including an NSMD type opening SOR1 that exposes the upper surfaces of the second-first pad 7-21 and the second-second pad 7-22. In addition, the first region 11-1 of the first protective layer 11 has a second circuit pattern 7 (e.g. traces or pads) means a region that does not exist.

At this time, a width of the opening SOR1 of the first region 11-1 of the first protective layer 11 is greater than a width of the second pad 7-2. Accordingly, the first region 11-1 of the first protective layer 11 is disposed at a certain distance from the second pad 7-2.

Here, a thickness t1 of the second circuit pattern 7 is 10 μm to 35 μm. In addition, a thickness t2 of the first region 11-1 of the first protective layer 11 is greater than the thickness t1 of the second circuit pattern 7. Specifically, the thickness t2 of the first region 11-1 of the first protective layer 11 is about 10 um to 30 um greater than the thickness t1 of the second circuit pattern 7. For example, the thickness t2 of the first region 11-1 of the first protective layer 11 is 20 μm to 65 μm.

At this time, a recess portion is provided at the first region 11-1 of the first protective layer 11 in the comparative example.

Specifically, a first recess portion u1 is provided at the first side wall 11-11 of the first region 11-1 of the first protective layer 11 adjacent to the second-first pad 7-21. In addition, a second recess portion u2 is provided at the second side wall 11-12 of the first region 11-1 of the first protective layer 11 adjacent to the second-second pad 7-22.

At this time, a depth of the opening SOR1 of the first region 11-1 of the first protective layer 11 in the comparative example corresponds to the thickness t2 of the first region 11-1 of the first protective layer 11. In addition, in the comparative example, exposure and curing of a lower region of the first region 11-1 are not completely achieved, and accordingly, the first recess portion u1 and the second recess portion u2 are formed at the first side wall 11-11 and the second side wall 11-12 of the first region 11-1.

Here, a horizontal distance w1 of the first recess portion u1 and the second recess portion u2 in the comparative example has a minimum of 40 μm. The horizontal distance w1 of the first recess portion u1 may refer to a horizontal distance from an outermost end of the first side wall 11-11 of the first region 11-1 to an innermost end of the first recess portion u1. In addition, the horizontal distance w1 of the second recess portion u2 may refer to a horizontal distance from an outermost end of a second side wall 11-12 of the first region 11-1 to an innermost end of the second recess portion u2.

In addition, the comparative example allows the width w2 of the first region 11-1 to be at least 90 um considering the horizontal distance w1 of the first recess portion u1 and the second recess portion u2.

In addition, a spacing w3 between the first side wall 11-11 of the first region 11-1 of the first protective layer 11 and the second-first pad 7-21, and a spacing w3 between the second side wall 11-12 and the second-second pad 7-22 has a minimum of 15 um.

Accordingly, in the comparative example, a spacing w4 between the second-first pad 7-21 and the second-second pad 7-22 at a position corresponding to the first region 11-1 of the first protective layer 11 has at least 120 um.

At this time, in the comparative example, a width of the first region 11-1 of the first protective layer 11 is reduced in order to reduce the spacing between the second-first pad 7-21 and the second-second pad 7-22.

For example, as shown in FIG. 1c, in the comparative example, the first region 11-1a of the first protective layer 11 has a width w2-1 of less than 90 um, and accordingly, the spacing between the second-first pad 7-21 and the second-second pad 7-22 was reduced. However, when the width w2-1 of the first region 11-1a is less than 90 um, a communication portion CR1 through which the first recess portion u1 and the second recess portion u2 communicate with each other is provided at the lower portion of the first region 11-1a in a process of forming the opening SOR1.

Accordingly, the comparative example has a problem in which a circuit short occurs as a portion 13-1 of the solder ball 13 penetrates into the communication portion CR1 in a process of reflowing the solder balls 13 after disposing them on the second-first pad 7-21 and the second-second pad 7-22. For example, in a comparative example, a portion 13-1 of the solder ball 13 disposed on the second-first pad 7-21 penetrates into the communication portion CR1 and contacts the second-second pad 7-22, and there is a problem that a short circuit occurs as the second-first pad 7-21 and the second-second circuit pattern 7, which should be electrically separated from each other, are connected to each other.

Meanwhile, as shown in FIG. 1d, the first protective layer 11 includes a second region 11-2 disposed between the second pad 7-2 and the trace 7-3.

The second region 11-2 of the first protective layer 11 may be a region covering the adjacent second circuit pattern 7 (for example, trace 7-3), and including an NSMD type opening SOR2 exposing the upper surface of the second pad 7-2.

In addition, a recess portion u3 is provided at the first side wall 11-21 of the second region 11-2 adjacent to the second pad 7-2. And, a horizontal distance w1 of the recess portion u3 has a minimum of 40 um.

In addition, in the comparative example, a width w5 between the first side wall 11-21 of the second region 11-2 and an edge 7-31 of the trace 7-3 covered by the second region 11-2 has a minimum of 45 um, considering the horizontal distance w1 of the recess portion u3.

Accordingly, in the comparative example, a spacing w6 between the second pad 7-2 and the trace 7-3 at a position corresponding to the second region 11-2 of the first protective layer 11 has a minimum of 60 um.

At this time, in the comparative example, the width w5 was reduced to reduce the spacing between the second pad 7-2 and the trace 7-3.

For example, as shown in FIG. 1e, in the comparative example, a distance between the first side wall 11-21 of the second region 11-2 and the edge 7-31 of the trace 7-3 covered by the second region 11-2 has a width w5-1 of less than 45 um, and so that the spacing w6-1 between the second pad 7-2 and the trace 7-3 was reduced. However, when the width w5-1 has a width smaller than 45 um, a problem occurs in which the edge of the trace 7-3 is exposed by the recess portion u3 generated in the process of forming the opening SOR2 of the second region 11-2.

In addition, in a process of reflowing the solder ball 14 after placing the solder ball 14 on the second pad 7-2 in the comparative example, a portion 14-1 of the solder ball 14 penetrates into the recess portion u3, and accordingly, there is a problem that a short circuit occurs due to contact with the side surface of the trace 7-3 exposed through the recess portion u3.

In addition, the third region 11-3 of the first protective layer 11 may be a region disposed on the first pad 7-1 and including an SMD type opening exposing the upper surface of the first pad 7-1. The third region 11-3 of the first protective layer 11 functions to protect an edge region of the upper surface of the first pad 7-1 while exposing the central region of the upper surface of the first pad 7-1.

As described above, a depth of the opening formed in the first protective layer 11 of the comparative example corresponds to the thickness t2 of the first protective layer 11, and accordingly, a recess portion with a horizontal distance of 40 um or more is provided at the side wall of the opening of the first protective layer 11. The horizontal distance refers to a horizontal distance from an outermost end of the side wall of the opening to an innermost end of the recess portion. In a comparative example, a design of the second circuit pattern 7 is designed considering the horizontal distance of the recess portion, and accordingly, there is a problem that the spacing between pads or traces constituting the second circuit pattern 7 or between pads and traces increases. Accordingly, in the comparative example, there is a problem in that the circuit integration is deteriorated and an overall volume of the circuit board in the horizontal direction increases accordingly.

In addition, the performance of electrical/electronic products has recently been improved, and accordingly, technologies for attaching a greater number of packages to a limited-sized substrate are being researched. Accordingly, there is a demand for finer circuit patterns. However, in the case of a package substrate using the circuit board of the comparative example, there is a limit to reducing the spacing between the second circuit patterns 7. Additionally, the number of functions processed by application processors (APs) has been increasing recently, as a result, it is becoming difficult to implement these functions with a single chip. However, when using the circuit board provided in the comparative example, it is difficult to mount two application processors (APs) performing different functions within a limited space.

The embodiment is intended to solve the problems of the comparative example and minimizes the horizontal distance of the recess portion corresponding to the undercut formed on the side wall of the solder resist. Furthermore, the embodiment reduces the spacing between circuit patterns by minimizing the horizontal distance of the recess portion. Furthermore, the embodiment allows mounting of a plurality of chips on one circuit board by reducing the spacing between the circuit patterns. For example, the embodiment provides a circuit board with a new structure capable of mounting multiple processor chips or memory chips performing different functions on a single circuit board, and a package substrate including the same.

### Electronic Device

Before describing an embodiment, an electronic device including a package substrate of an embodiment will be briefly described. An electronic device includes a main board (not shown). The main board may be physically and/or electrically connected to various components. For example, the main board may be connected to the package substrate of the embodiment. Various semiconductor devices may be mounted on the package substrate. The chip mounted on the package substrate can include a memory chip such as a volatile memory (e.g., DRAM), a non-volatile memory (e.g., ROM), or a flash memory, an application processor (AP) chip such as a central processor (CPU), a graphic processor (GPU), antenna chip, a digital signal processor, a cryptographic processor, a microprocessor, and a microcontroller, or a logic chip such as analog-digital converters and ASICs (application-specific ICs).

Additionally, the embodiment provides a circuit board and a package substrate that enable a pitch of the pad to be refined and to mount at least two different types of chips on one substrate according to the refinement of the pitch. Furthermore, the embodiment provides a circuit board and package substrate that allow more traces to be disposed between mounting pads having a smaller pitch than the comparative example.

In this case, the electronic device may include a smart phone, a personal digital assistant, a digital video camera, a digital still camera, a network system, a computer, a monitor, a tablet, a laptop, a netbook, a television, a video game, a smart watch, an automotive, and the like. However, the embodiment is not limited thereto, and may be any other electronic device that processes data in addition to these.

### Embodiment

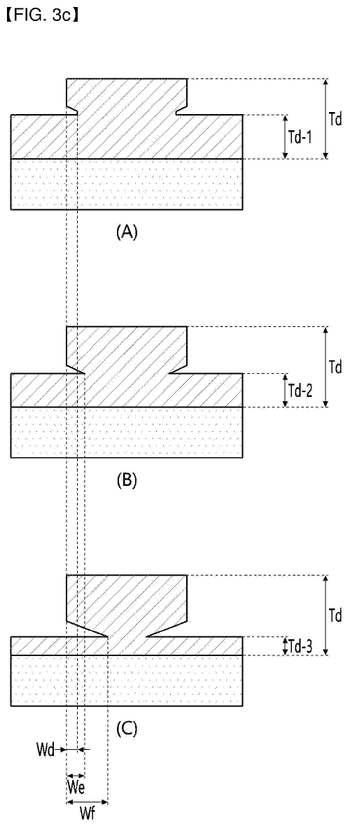

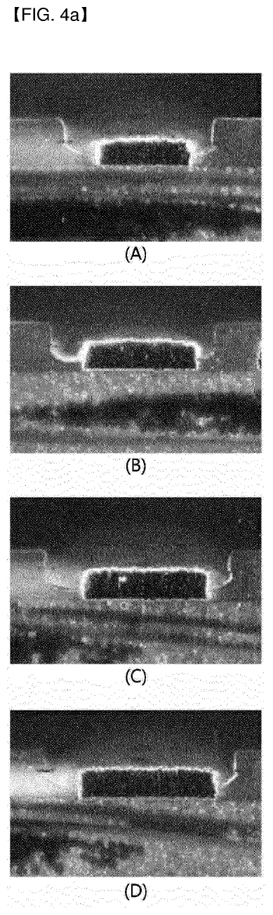

FIG. 2a is a cross-sectional view of a circuit board according to an embodiment, and FIG. 2b is a plan view of the circuit board of FIG. 2a viewed from an top.

First, referring to FIGS. 2a and 2b, an overall structure of the circuit board according to the embodiment will be described. However, in FIG. 2b, an entire upper surface of a trace 124 of a first circuit pattern layer 120 is shown as exposed, but this is for convenience of explanation, and substantially, the traces 124 of the first circuit pattern layer 120 are covered by the second portion 190b of the first protective layer 190.

Referring to FIGS. 2a and 2b, the circuit board includes an insulating layer 110, a circuit pattern layer, a via, and a protective layer.

The insulating layer 110 may have a multiple layer structure. For example, the insulating layer 110 may include a first insulating layer 111, a second insulating layer 112, and a third insulating layer 113. At this time, the circuit board is shown in the drawing as having a three-layer structure based on the number of insulating layers, but it is not limited to this. For example, the circuit board may have a structure of two or less layers based on the number of insulating layers, or alternatively, may have a structure of four or more layers.

For example, the first insulating layer 111 may be a first outermost insulating layer disposed at an first outermost side in a multi-layer structure. For example, the first insulating layer 111 may be an insulating layer disposed at an uppermost side of the circuit board. The second insulating layer 112 may be an inner insulating layer disposed at an inside of a multi-layered circuit board. The third insulating layer 113 may be a second outermost insulating layer disposed at the second outermost side in a multi-layer structure. For example, the third insulating layer 113 may be an insulating layer disposed at a lowermost side of the circuit board. In addition, the inner insulating layer is shown as being composed of one layer, but differently, it may be composed of two or more layers.

The insulating layer 110 is a board equipped with an electric circuit whose wiring can be changed, and may include a print, a wiring board, and an insulating board made of an insulating material capable of forming circuit patterns on the surface.

For example, at least one of the insulating layer 110 may be rigid or flexible. For example, at least one of the insulating layer 110 may include glass or plastic. Specifically, the insulating layer 110 may include a chemically tempered/semi-tempered glass, such as soda lime glass, aluminosilicate glass, etc., a tempered or flexible plastic such as polyimide (PI), polyethylene terephthalate (PET), propylene glycol (PPG), polycarbonate (PC), etc., or sapphire.

In addition, at least one of the insulating layer 110 may include an optically isotropic film. For example, at least one of the insulating layer 110 may include cyclic olefin copolymer (COC), cyclic olefin polymer (COP), optically isotropic PC, optically isotropic polymethylmethacrylate (PMMA), or the like.

In addition, at least one of the insulating layer 110 may be formed of a material including an inorganic filler and an insulating resin. For example, at least one of the insulating layer 330 may be formed of a resin containing reinforcing materials such as inorganic fillers such as silica and alumina together with a thermosetting resin such as an epoxy resin or a thermoplastic resin such as polyimide, specifically Ajinomoto Build-up Film (ABF), FR-4, Bismaleimide Triazine (BT), Photo Imageable Dielectric resin (PID), BT, or the like.

In addition, at least one of the insulating layers 110 may have a partially curved surface and be curved. That is, at least one of the insulating layers 110 is partially flat, and at least one of the insulating layers 110 may have a partially curved surface and be bent. In detail, at least one end of the insulating layer 110 may have a curved surface and be bent, or at least one end of the insulating layer 110 has a surface with random curvature and may be curved or bent.

A circuit pattern layer may be disposed on a surface of the insulating layer 110.

For example, a first circuit pattern layer 120 may be disposed on a first or upper surface of the first insulating layer 111. For example, a second circuit pattern layer 130 may be disposed between a second surface or lower surface of the first insulating layer 111 and a first surface or upper surface of the second insulating layer 112. For example, a third circuit pattern layer 140 may be disposed between a second surface or lower surface of the second insulating layer 112 and a first surface or upper surface of the third insulating layer 113. For example, a fourth circuit pattern layer 150 may be disposed on a second or lower surface of the third insulating layer 113. A first circuit pattern layer 120 may be a circuit pattern layer disposed at a first outermost side or uppermost side of the circuit board. Additionally, the second circuit pattern layer 130 and the third circuit pattern layer 140 may be inner circuit pattern layers disposed inside the circuit board. Additionally, the fourth circuit pattern layer 150 may be a circuit pattern layer disposed at a second outermost side or lowermost side of the circuit board.

The first circuit pattern layer 120, the second circuit pattern layer 130, the third circuit pattern layer 140, and the fourth circuit pattern layer 150 is a wire that transmits electrical signals and may be formed of a metal material with high electrical conductivity. The first circuit pattern layer 120, the second circuit pattern layer 130, the third circuit pattern layer 140, and the fourth circuit pattern layer 150 may be formed of at least one metal material selected from among gold (Au), silver (Ag), platinum (Pt), titanium (Ti), tin (Sn), copper (Cu), and zinc (Zn). In addition, the first circuit pattern layer 120, the second circuit pattern layer 130, the third circuit pattern layer 140, and the fourth circuit pattern layer 150 may be formed of paste or solder paste including at least one metal material selected from among gold (Au), silver (Ag), platinum (Pt), titanium (Ti), tin (Sn), copper (Cu), and zinc (Zn), which are excellent in bonding force. Preferably, the first circuit pattern layer 120, the second circuit pattern layer 130, the third circuit pattern layer 140, and the fourth circuit pattern layer 150 may be formed of copper (Cu) having high electrical or thermal conductivity and a relatively low cost.

The first circuit pattern layer 120, the second circuit pattern layer 130, the third circuit pattern layer 140, and the fourth circuit pattern layer 150 can be formed using an additive process, a subtractive process, a modified semi additive process (MSAP) and a semi additive process (SAP), which is a typical circuit board manufacturing process, and a detailed description will be omitted here.

Meanwhile, each of the first to fourth circuit pattern layers 120, 130, 140, and 150 includes traces and pads.

The trace refers to a long line-shaped wiring that transmits electrical signals. Additionally, the pad may refer to a mounting pad on which components such as chips are mounted, a core pad or BGA pad for connection to an external board, or a via pad connected to a via.

A via may be formed in the insulating layer 110. The via is formed to pass through the insulating layer 110, and thus can electrically connect circuit pattern layers arranged in different layers.

For example, a first via 160 may be formed in the first insulating layer 111. The first via 160 passes through the first insulating layer 111, and thus can electrically connect the first circuit pattern layer 120 and the second circuit pattern layer 130.

For example, a second via 170 may be formed in the second insulating layer 112. The second via V2 passes through the second insulating layer 112, and thus can electrically connect the second circuit pattern layer 130 and the third circuit pattern layer 140. At this time, the second insulating layer 112 may be a core layer. And, when the second insulating layer 112 is a core layer, the second via 170 may have an hourglass shape.

For example, a third via V3 may be formed in the third insulating layer 113. The third via V3 passes through the third insulating layer 113, and thus can electrically connect the third circuit pattern layer 140 and the fourth circuit pattern layer 150.

The vias 160, 170, and 180 as described above may be formed by filling the inside of the via hole formed in each insulating layer with a metal material. The via hole may be formed by any one of mechanical, laser, and chemical processing. When the via hole is formed by mechanical processing, a method such as milling, drilling and routing may be used, when the via hole is formed by laser processing, a method of UV or CO2 laser may be used, when the via hole is formed by chemical processing, a chemical including amino silane, ketones, or the like may be used. Accordingly, at least one insulating layer among the plurality of insulating layers may be opened.

When the via hole is formed, the vias 160, 170, and 180 may be formed by filling the inside of the through hole with a conductive material. The metal material forming the vias 160, 170, and 180may be any one selected from among copper (Cu), silver (Ag), tin (Sn), gold (Au), nickel (Ni), and palladium (Pd). In addition, the conductive material may be filled by any one of electroless plating, electroplating, screen printing, sputtering, evaporation, ink jetting, and dispensing, or a combination thereof.

Meanwhile, a first protective layer 190 may be disposed on the first or upper surface of the first insulating layer 111. The first protective layer 190 may include a solder resist. The first protective layer 190 may include an opening SOR exposing a surface of the first circuit pattern layer 190. For example, the first protective layer 190 may include an opening SOR that exposes the pads 121, 122, and 123 of the first circuit pattern layer 120.

Correspondingly, a second protective layer 195 may be disposed on the second surface of the third insulating layer 113. The second protective layer 195 may include a solder resist. The second protective layer 195 may include an opening (not shown) exposing a surface of the pad (not shown) of the fourth circuit pattern layer 150.

At this time, the first protective layer 190 may have a stepped structure. For example, the first protective layer 190 may include a first portion 190a disposed on the upper surface of the first insulating layer 111, and a second portion 190b disposed on the first portion 190a.

The first portion 190a of the first protective layer 190 may contact an upper surface of the first insulating layer 111. Additionally, the first portion 190a of the first protective layer 190 may contact a portion of a side surface of the first circuit pattern layer 120. Meanwhile, the first portion 190a of the first protective layer 190 may expose at least a portion of a side surface of the first circuit pattern layer 120.

Specifically, a thickness of the first portion 190a of the first protective layer 190 may be smaller than a thickness of the first circuit pattern layer 120. For example, an upper surface of the first portion 190a of the first protective layer 190 may be positioned lower than an upper surface of the first circuit pattern layer 120. Accordingly, the first portion 190a of the first protective layer 190 may expose an upper region of the side surface of the first circuit pattern layer 120 while covering a lower region of the side surface of the first circuit pattern layer 120.

The second portion 190b of the first protective layer 190 may be disposed on an upper surface of a portion of the first portion 190a of the first protective layer 190 and an upper surface of a portion of the first circuit pattern layer 120. Additionally, the second portion 190b of the first protective layer 190 may include an opening SOR exposing another portion of an upper surface of the first circuit pattern layer 120. At this time, a width of the opening SOR of the second portion 190b of the first protective layer 190 may be greater than a width of the first pad 121 of the first circuit pattern layer 120 exposed through the opening SOR. Accordingly, the opening SOR of the second portion 190b of the first protective layer 190 may expose the upper surface of the first portion 190a of the first protective layer 190 adjacent to the first pad 121 and the upper region of the side surface of the first pad 121.

At this time, a depth of the opening SOR formed in the first protective layer 190 in the embodiment may be smaller than a thickness of the first protective layer 190. For example, the opening SOR of the first protective layer 190 has a depth corresponding to the thickness of the second portion 190b minus a thickness of the first portion 190a from a total thickness of the first protective layer 190. Therefore, in the embodiment, the opening SOR is formed only in the second portion 190b excluding the first portion 190a of the first protective layer 190, so that a horizontal distance of a recess portion corresponding to an undercut formed in the first protective layer 190 can be reduced compared to the comparative example. The reason why the horizontal distance of the recess portion is reduced will be explained below.

Meanwhile, the first protective layer 190 may include a first region 191, a second region 192, and a third region 193.

The first region 191 of the first protective layer 190 may be a region with an opening exposing an upper surface of the first pad 121 of the first circuit pattern layer 120. Additionally, the first region 191 of the first protective layer 190 may be a region in which a portion of the first circuit pattern layer 120 is disposed adjacent to the first pad 121. For example, the first region 191 of the first protective layer 190 may be a region where the first pad 121 and an adjacent pattern disposed adjacent to the first pad 121 exist. The adjacent pattern may be either the trace 124 of the first circuit pattern layer 120 or the third pad 123. Accordingly, the first region 191 of the first protective layer 190 may be formed in a region where the trace 124 is disposed adjacent to the first pad 121. For example, the first region 191 of the first protective layer 190 may be formed in a region where the first pad 121 and the third pad 123 adjacent to the first pad 121 are disposed. In addition, the second portion 190b of the first region 191 of the first protective layer 190 may include an opening that exposes the first pad 121 while covering upper surfaces of the trace 124 or the third pad 121.

The second region 192 of the first protective layer 190 may be a region with an opening exposing the upper surface of the second pad 122 of the first circuit pattern layer 120. In addition, the second region 192 of the first protective layer 190 may be a region in which another first circuit pattern layer 120 is not disposed between the plurality of second pads 122 while exposing the upper surfaces of the plurality of second pads 122 adjacent to each other.

The third region 193 of the first protective layer 190 may be a region where an opening is formed exposing the upper surface of the third pad 123 of the first circuit pattern layer 120. For example, the third region 193 of the first protective layer 190 may be a region including an opening smaller than a width of the third pad 123. For example, the third region 193 of the first protective layer 190 may be a region that covers an edge region of an upper surface of the third pad 123 while exposing a central region of the upper surface of the third pad 123.

The first region 191, second region 192, and third region 193 of the first protective layer 190 will be described in more detail below.

Meanwhile, in the embodiment, the first protective layer 190 includes a first portion 190a and a second portion 190b having steps. And, in the first protective layer 190 in the embodiment, a recess portion corresponding to an undercut is formed at a side wall of the second portion 190b. At this time, in the comparative example, a recess portion was substantially formed at the sidewall of the first portion of the first protective layer. Accordingly, in the comparative example, the recess portion formed in the first protective layer has a horizontal distance of at least 40 μm or more. On the other hand, in the embodiment, when forming an opening in the first protective layer 190, the opening has a depth corresponding to a thickness of the second portion 190b in a total thickness of the first protective layer 190. Accordingly, a horizontal distance of a recess portion in the embodiment is set to be 35% or less of the horizontal distance of the recess portion in the comparative example. For example, a horizontal distance of a recess portion in the embodiment is set to be less than 25% of the horizontal distance of the recess portion in the comparative example. For example, a horizontal distance of a recess portion in the embodiment is set to be less than 15% of the horizontal distance of the recess portion in the comparative example. For example, a horizontal distance of a recess portion in the embodiment is set to be less than 5% of the horizontal distance of the recess portion in the comparative example.

Specifically, in the embodiment, a recess portion is provided at the second portion 190b of the first protective layer 190. And, in the embodiment, a horizontal distance of the recess portion may exceed 0 μm and be 13 μm or less. For example, in an embodiment, the horizontal distance of the recess portion may exceed 0 μm and be 10 μm or less. For example, in an embodiment, the horizontal distance of the recess portion may exceed 0 μm and be 6 μm or less. For example, in an embodiment, the horizontal distance of the recess portion may exceed 0 μm and be 2 μm or less.

Here, the horizontal may mean a plane parallel to a plane where the first circuit pattern layer 120 extends in the circuit board of the embodiment. Accordingly, the horizontal distance may mean a distance in a direction of a plane parallel to a plane where the first circuit pattern layer 120 extends. For example, the horizontal distance may mean a distance in a first direction corresponding to a width direction of the first circuit pattern layer 120. For example, the horizontal distance may mean a distance in a second direction corresponding to a longitudinal direction of the first circuit pattern layer 120. For example, the horizontal distance may mean a distance in a third direction corresponding to a diagonal direction between the width direction and the longitudinal direction of the first circuit pattern layer 120.

Hereinafter, the reason why the horizontal distance of the recess portion in the embodiment may be reduced compared to the comparative example, and a shape of each region of the first protective layer 190 and the horizontal distance of the recess portion will be described.

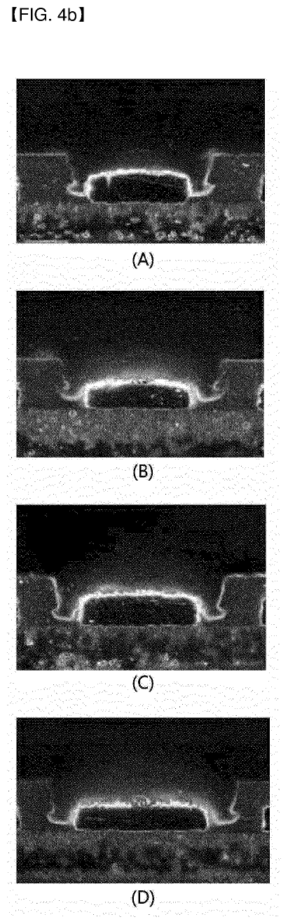

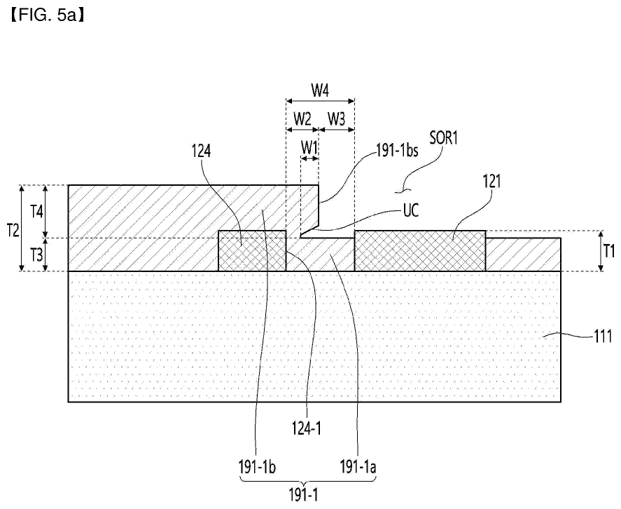

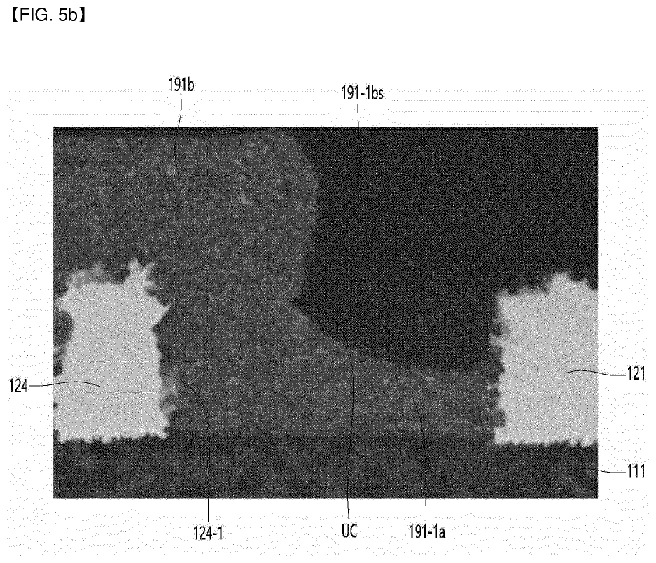

FIG. 3a is a view for explaining a process of exposing and curing a solder resist layer according to an embodiment, FIG. 3b is a view for explaining a horizontal distance of a recess portion according to a thickness of a solder resist layer, and FIG. 3c is a view for explaining a horizontal distance of a recess portion according to a development depth of a solder resist layer.

Referring to FIG. 3a, a process of forming the first protective layer 190 includes a process of forming a solder resist layer 190L on the first insulating layer 111 and a process of exposing the remaining region 190L1 of the solder resist layer 190L excluding the region 190L2 where the opening SOR will be formed. At this time, the solder resist layer 190L can be formed by a screen printing method, a roller coating method, a curtain coating method, a spray coating method, and a solder resist film lamination method. However, the embodiment is not limited thereto. The screen printing is a method of directly printing a solder resist pattern using a printing plate. In this method, an exposure process and a developing process can be omitted, and a curing process can be performed immediately. The roller coating method is a method of coating a substrate by applying a thin layer of photocurable resin, which has a lower viscosity than that used in the screen printing, on a roller made of rubber or other material. However, this method may make it difficult to control the thickness of the solder resist layer coated depending on the substrate and create a uniform coating layer. The curtain coating method uses a photocurable resin with a lower viscosity than that used in roller coating, and is a method of coating the solder resist layer by sending the photocurable resin through a slit (not shown) and passing the substrate under the slit. This method can achieve very uniform coating quality and can be applied without limitation to a size of the substrate. The spray coating method is a method of coating by spraying photocurable resin ink, and may have the advantage of being easy to control the thickness of the solder resist layer.

Meanwhile, the exposure process may include a process of forming a mask (not shown) on a region 190L2 where the opening SOR will be formed to prevent light such as ultraviolet rays from transmitting, and a process of irradiating light such as ultraviolet rays to the remaining region 190L1.

At this time, even if uniform light is irradiated to the remaining region 190L1, an amount of light irradiated in a thickness direction of the remaining region 190L1 varies, and accordingly, a degree of exposure of the remaining region 190L1 in the thickness direction varies.

For example, the remaining region 190L1 where the exposure is performed can be divided into an upper region 190L1T adjacent to an upper surface of the solder resist layer 190L, a lower region 190L1B adjacent to the lower surface of the solder resist layer 190L, and a middle region 190L1C between the upper region 190L1T and the lower region 190L1B, based on the thickness direction.

In addition, when light is irradiated from the upper surface of the solder resist layer 190L, the amount of light irradiated to the upper region 190L1T, the amount of light irradiated to the middle region 190L1C, and the amount of light irradiated to the lower region 190L1B is different from each other. Specifically, the amount of irradiated light decreases from the upper region 190L1T to the lower region 190L1B.

Accordingly, when an exposure degree of the upper region 190L1T of the solder resist layer 190L is assumed to be 100% by the exposure process, an exposure degree of the middle region 190L1C is about 90% less than the exposure degree of the upper region 190L1T, and an exposure degree of the lower region 190L1B is less than 80% of the exposure degree of the middle region 190L1C.

In addition, a process of curing the exposed remaining region 190L1 may be performed after the exposure process described above. At this time, the degree of exposure in each region is different, and the degree of curing also varies accordingly. For example, when the curing degree of the upper region 190L1T of the solder resist layer 190L is 100%, the curing degree of the middle region 190L1C is about 90% less than the curing degree of the upper region 190L1T, and the curing degree of the lower region 190L1B is less than the curing degree of the middle region 190L1C of 80% or less.

Accordingly, after the curing process proceeds, when the development of the region 190L2 where the opening SOR is to be formed is performed without the curing being performed, the lower region 190L1B, which has not been completely cured, is also developed and etched, resulting in the formation of a recess portion like an undercut.

In addition, recently, in order to stably protect the first circuit pattern layer 120, a thickness of the solder resist layer 190L is gradually increasing. Accordingly, the degree of curing of the lower region 190L1B decreases as the thickness of the solder resist layer 190L increases, and accordingly, a horizontal distance of the recess portion formed in the lower region 190L1B is gradually increasing.

Specifically, referring to FIG. 3b, a horizontal distance of the recess portion may increase in proportion to a thickness of the solder resist layer 190L. ‘I’ in FIG. 3b refers to an uppermost insulating layer, and S1, S2, and S3 refer to a solder resist layer formed on the uppermost insulating layer.

For example, as shown in (a) of FIG. 3b, when forming an opening having a first depth Ta in the solder resist layer S1 having a first thickness Ta, a recess portion may have a horizontal distance Wa of ‘a’.

In addition, as shown in (b) of FIG. 3b, when forming an opening of a second depth Tb greater than the first depth Ta in the solder resist layer S2 having a second thickness Tb greater than the first thickness Ta, a recess portion has a horizontal distance Wb of ‘b’ that is greater than the horizontal distance of ‘a’.

In addition, as shown in (c) of FIG. 3b, when forming an opening of a third depth Tc greater than the first depth Ta and the second depth Tb in the solder resist layer S3 having a third thickness Tc greater than the second thickness Tb, a recess portion has a horizontal distance Wc of ‘c’ that is greater than the horizontal distance of ‘a’ and ‘b’.

As shown in FIG. 3b, when the opening is formed to have a depth corresponding to the thickness of the solder resist layer, it can be seen that the horizontal distance of the recess portion increases in proportion to the thickness of the solder resist layer.

In addition, referring to FIG. 3c, the horizontal distance of the recess portion may increase in proportion to a depth of the opening formed in the solder resist layer 190L.

For example, as shown in (a) of FIG. 3c, when forming an opening while leaving a first remaining region Td-1 in a solder resist layer having a fourth thickness Td, the recess portion may have a horizontal distance Wd of ‘d’.

In addition, as shown in (b) of FIG. 3c, when forming an opening while leaving a second remaining region Td-2 thinner than the first remaining region Td-1 in the solder resist layer having the fourth thickness Td, the recess portion has a horizontal distance We of ‘e’ that is greater than the horizontal distance Wd of ‘d’.

In addition, as shown in (c) of FIG. 3c, when forming an opening while leaving a third remaining region Td-3 thinner than the first and second remaining regions Td-1 and Td-2 in the solder resist layer having the fourth thickness Td, the recess portion has a horizontal distance Wf of ‘f’ that is greater than the horizontal distance Wd of ‘d’ and the horizontal distance We of ‘e’.

As shown in FIG. 3C, when a portion of the solder resist layer is removed to form an opening, it can be seen that a horizontal distance of a recess portion decreases in inverse proportion to a thickness of the remaining region that is not removed from the solder resist layer.

Accordingly, as described above, the opening SOR is not formed to correspond to the entire thickness of the first protective layer, but the embodiment allows forming the opening SOR only for the second portion 190b excluding the first portion 190a of the first protective layer 190, so that a horizontal distance of the recess portion formed in the second portion 190b can be reduced compared to the comparative example.

Hereinafter, experimental results of a horizontal distance of a recess portion in a case of forming the first protective layer according to the embodiment will be described.

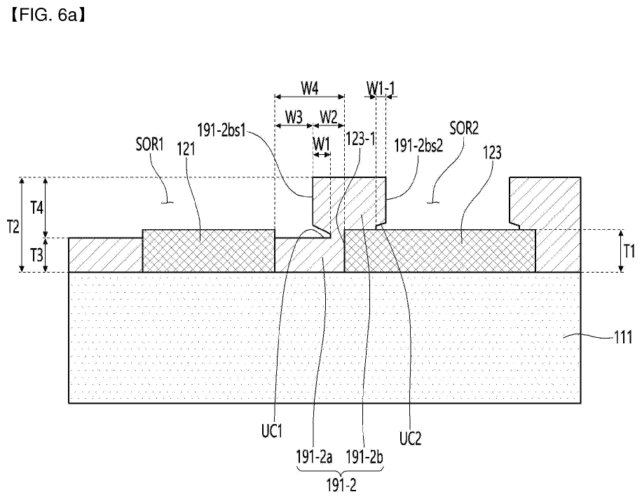

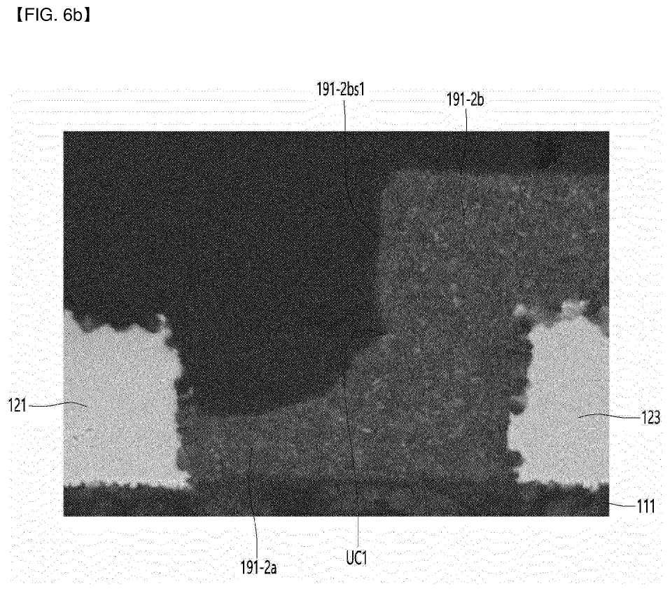

FIG. 4a is a view showing results of an experiment on a horizontal distance of a recess portion in a solder resist layer made of a first insulating material, and FIG. 4b is a view for explaining results of an experiment on a horizontal distance of a recess portion in a solder resist layer made of a second insulating material different from the first insulating material.

At this time, a first insulating material and a second insulating material may be materials constituting the solder resist layer, and may be different from each other. For example, a fact that the first insulating material and the second insulating material are different from each other may mean that a type or content of a filler included in the solder resist layer is different from each other, but is not limited thereto.

First, (A) in FIG. 4a shows the recess portion in a first protective layer of a first insulating material under a condition that a width of a first pad has a first-first width and an opening has a first-second width (e.g., 80 um) greater than the first-first width. At this time, a difference value between the first-first width and the first-second width may be ‘A’. And, under the above conditions, when developing only a second portion of the first protective layer excluding a first portion to form an opening having the first-second width, a horizontal distance of the recess portion formed in the second portion was examined.

(B) in FIG. 4a shows the recess portion in a first protective layer of a first insulating material under a condition that a width of a first pad has a second-first greater than the first-first width and an opening has a second-second width (e.g., 95 um) greater than the second-first width. At this time, a difference value between the second-first width and the second-second width may be ‘A’, which is the same as (A) in FIG. 4a. And, under the above conditions, when developing only a second portion of the first protective layer excluding a first portion to form an opening having the second-second width, a horizontal distance of the recess portion formed in the second portion was examined.

(C) in FIG. 4a shows the recess portion in a first protective layer of a first insulating material under a condition that a width of a first pad has a third-first greater than the second-first width and an opening has a third-second width (e.g., 100 um) greater than the third-first width. At this time, a difference value between the third-first width and the third-second width may be ‘A’, which is the same as (A) and (B) in FIG. 4a. And, under the above conditions, when developing only a second portion of the first protective layer excluding a first portion to form an opening having the first-second width, a horizontal distance of the recess portion formed in the second portion was examined.

(D) in FIG. 4a shows the recess portion in a first protective layer of a first insulating material under a condition that a width of a first pad has a fourth-first greater than the third-first width and an opening has a fourth-second width (e.g., 110 um) greater than the fourth-first width. At this time, a difference value between the fourth-first width and the fourth-second width may be ‘A’, which is the same as (A) to (C) in FIG. 4a. And, under the above conditions, when developing only a second portion of the first protective layer excluding a first portion to form an opening having the first-second width, a horizontal distance of the recess portion formed in the second portion was examined.

In the case of (A) of FIG. 4a, it was confirmed that a minimum horizontal distance of the recess portion was 0.57 um, and a maximum horizontal distance was 1.82 um, and accordingly, an average horizontal distance of the recess portion was 1.40 um, which was confirmed to be significantly reduced compared to the comparative example.

In the case of (B) of FIG. 4a, it was confirmed that a minimum horizontal distance of the recess portion was 0.62 um, and a maximum horizontal distance was 2.25 um, and accordingly, an average horizontal distance of the recess portion was 1.37 um, which was confirmed to be significantly reduced compared to the comparative example.

In the case of (C) of FIG. 4a, it was confirmed that a minimum horizontal distance of the recess portion was 0.10 um, and a maximum horizontal distance was 2.22 um, and accordingly, an average horizontal distance of the recess portion was 1.05 um, which was confirmed to be significantly reduced compared to the comparative example.

In the case of (D) of FIG. 4a, it was confirmed that a minimum horizontal distance of the recess portion was 0.68 um, and a maximum horizontal distance was 2.44 um, and accordingly, an average horizontal distance of the recess portion was 1.44 um, which was confirmed to be significantly reduced compared to the comparative example.

Meanwhile, (A) in FIG. 4b shows the recess portion in a first protective layer of a second insulating material under a condition that a width of a first pad has a first-first width and an opening has a first-second width (e.g., 80 um) greater than the first-first width. At this time, a difference value between the first-first width and the first-second width may be ‘A’. And, under the above conditions, when developing only a second portion of the first protective layer excluding a first portion to form an opening having the first-second width, a horizontal distance of the recess portion formed in the second portion was examined.

(B) in FIG. 4b shows the recess portion in a first protective layer of a second insulating material under a condition that a width of a first pad has a second-first greater than the first-first width and an opening has a second-second width (e.g., 95 um) greater than the second-first width. At this time, a difference value between the second-first width and the second-second width may be ‘A’, which is the same as (A) in FIG. 4b. And, under the above conditions, when developing only a second portion of the first protective layer excluding a first portion to form an opening having the second-second width, a horizontal distance of the recess portion formed in the second portion was examined.

(C) in FIG. 4b shows the recess portion in a first protective layer of a second insulating material under a condition that a width of a first pad has a third-first greater than the second-first width and an opening has a third-second width (e.g., 100 um) greater than the third-first width. At this time, a difference value between the third-first width and the third-second width may be ‘A’, which is the same as (A) and (B) in FIG. 4b. And, under the above conditions, when developing only a second portion of the first protective layer excluding a first portion to form an opening having the first-second width, a horizontal distance of the recess portion formed in the second portion was examined.

(D) in FIG. 4b shows the recess portion in a first protective layer of a second insulating material under a condition that a width of a first pad has a fourth-first greater than the third-first width and an opening has a fourth-second width (e.g., 110 um) greater than the fourth-first width. At this time, a difference value between the fourth-first width and the fourth-second width may be ‘A’, which is the same as (A) to (C) in FIG. 4b. And, under the above conditions, when developing only a second portion of the first protective layer excluding a first portion to form an opening having the first-second width, a horizontal distance of the recess portion formed in the second portion was examined.

In the case of (A) of FIG. 4b, it was confirmed that a minimum horizontal distance of the recess portion was 4.40 um, and a maximum horizontal distance was 5.83 um, and accordingly, an average horizontal distance of the recess portion was 4.61 um, which was confirmed to be significantly reduced compared to the comparative example.

In the case of (B) of FIG. 4b, it was confirmed that a minimum horizontal distance of the recess portion was 3.35 um, and a maximum horizontal distance was 5.50 um, and accordingly, an average horizontal distance of the recess portion was 4.74 um, which was confirmed to be significantly reduced compared to the comparative example.

In the case of (C) of FIG. 4b, it was confirmed that a minimum horizontal distance of the recess portion was 4.11 um, and a maximum horizontal distance was 6.07 um, and accordingly, an average horizontal distance of the recess portion was 5.07 um, which was confirmed to be significantly reduced compared to the comparative example.

In the case of (D) of FIG. 4b, it was confirmed that a minimum horizontal distance of the recess portion was 4.41 um, and a maximum horizontal distance was 6.12 um, and accordingly, an average horizontal distance of the recess portion was 5.36 um, which was confirmed to be significantly reduced compared to the comparative example.

Specifically, the embodiment forms an opening exposing the pad of the first circuit pattern layer 120 by opening only the second portion 190b excluding the first portion 190a of the first protective layer 190, so that the horizontal distance of the recess portion can be significantly reduced compared to the comparative example.

Hereinafter, the structure of each region of the first protective layer of the embodiment will be described.

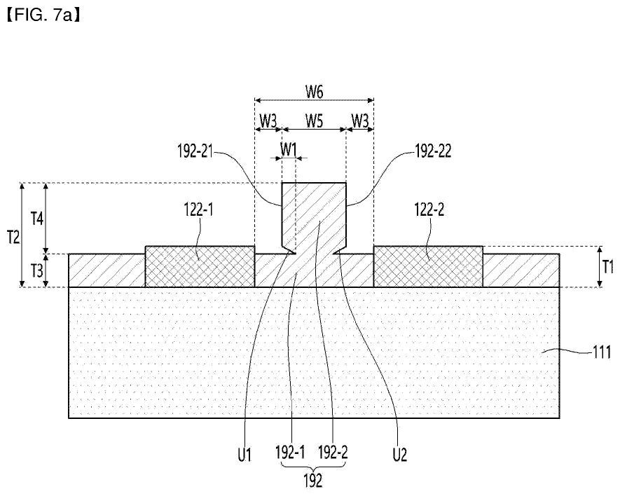

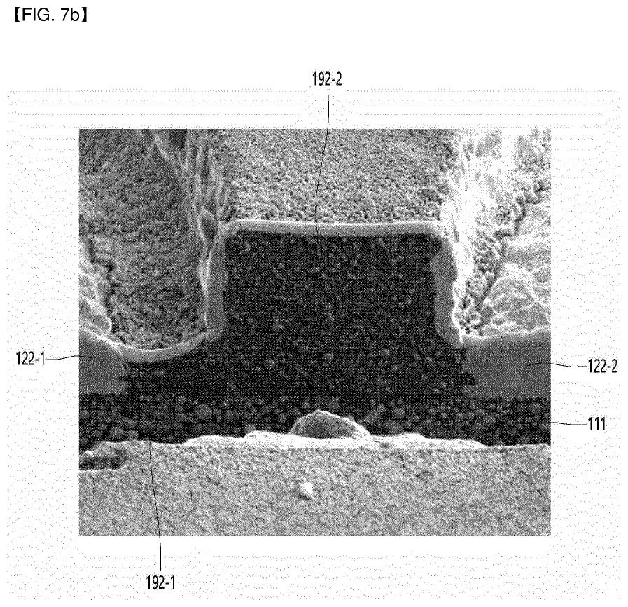

FIG. 5a is a view showing a first-first region of a first region of a first protective layer of FIG. 2a, and FIG. 5b is a view showing a SAM photograph of a circuit board corresponding to FIG. 5a. FIG. 5A is a cross-sectional view taken along line L1 of FIG. 2b.

Before explaining FIGS. 5a and 5b, the first region 191 of the first protective layer 190 of the embodiment includes a first portion 191-1a and 191-2a and a second portion 191-1b and 191-2b.

For example, the first region 191 of the first protective layer 190 may include a first portion 191-1a at one side of the first pad 121 and a first portion 191-2a on the other side of the first pad 121, based on the first pad 121. In addition, the first region 191 of the first protective layer 190 may include a second portion 191-1b on the first portion 191-1a at one side of the first pad 121 and a second portion 191-2b on the first portion 191-2a at the other side of the first pad 121.

Hereinafter, for convenience of explanation, the first region 191 at one side of the first pad 121 is called the first-first region 191-1, and the first region 191 at the other side of the first pad 121 is called a first-second region 191-2.

Referring to FIGS. 5A and 5B, the first region 191 of the first protective layer 190 may be a region where a first opening SOR1 exposing the upper surface of the first pad 121 of the first circuit pattern layer 120 is formed. In addition, the first region 191 of the first protective layer 190 may be a region in which a portion (e.g., adjacent pattern) of the first circuit pattern layer 120 adjacent to the first pad 121 is disposed.

The adjacent pattern may be either the trace 124 of the first circuit pattern layer 120 or the third pad 123. Accordingly, the first region 191 of the first protective layer 190 may be a region where the trace 124 adjacent to the first pad 121 is disposed or a region where the third pad 123 is disposed.

Accordingly, the first region 191 of the first protective layer 190 may include a first-first region 191-1 between the first pad 121 and the trace 124 and a first-second region 191-2 between the first pad 121 and the third pad 123. And, FIG. may show a first-first region 191-1, which is part of the first region 191.

In addition, the first-first region 191-1 of the first protective layer 190 includes a first-first portion 191-1a disposed between the first pad 121 of the first circuit pattern layer 120 and the trace 124. The first-first portion 191-1a may also be referred to as a first portion of the first region 191 of the first protective layer 190.

In addition, the first-first region 191-1 of the first protective layer 190 may include a first-second portion 191-1b having an opening exposing the upper surface of the first pad 121 while covering the trace 124 on the first-first portion 191-1a of the first-first region 191-1. The first-second portion 191-1b may also be referred to as a second portion of the first region 191 of the first protective layer 190.

At this time, a thickness T1 of the first pad 121 of the first circuit pattern layer 120 may be 10 μm to 35 μm. For example, a thickness T1 of the first pad 121 of the first circuit pattern layer 120 may be 12 μm to 30 μm. For example, a thickness T1 of the first pad 121 of the first circuit pattern layer 120 may be 15 μm to 25 μm. If the thickness T1 of the first pad 121 of the first circuit pattern layer 120 is less than 10 μm, the resistance of the first pad 121 may increase, and signal loss may increase accordingly. If the thickness T1 of the first pad 121 of the first circuit pattern layer 120 is greater than 35 um, it is difficult to miniaturize the first pad 121, and as a result, the degree of integration of the circuit board may decrease and an overall volume of the circuit board may increase.

Meanwhile, a thickness T2 of the first-first region 191-1 of the first protective layer 190 may be 110% to 200% of the thickness T1 of the first pad 121. For example, a thickness T2 of the first-first region 191-1 of the first protective layer 190 may be 120% to 190% of the thickness T1 of the first pad 121. The thickness T2 of the first-first region 191-1 of the first protective layer 190 may be 130% to 180% of the thickness T1 of the first pad 121.

If the thickness T2 of the first-first region 191-1 of the first protective layer 190 is less than 110% of the thickness T1 of the first pad 121, a problem may occur in which the trace 124 is not stably protected by the first protective layer 190. In addition, if the thickness T2 of the first-first region 191-1 of the first protective layer 190 is greater than 200% of the thickness T1 of the first pad 121, a total thickness of the circuit board may increase. In addition, if the thickness T2 of the first-first region 191-1 of the first protective layer 190 is greater than 200% of the thickness T1 of the first pad 121, a thickness T4 of the first-second portion 191-1b increases, and accordingly, a horizontal distance W1 of the recess portion (UC, undercut) formed at the side wall 191-1bs of the first-second portion 191-1b may increase.

A thickness T3 of the first-first portion 191-1a in the first-first region 191-1 may be smaller than the thickness T1 of the first pad 121. In addition, the thickness T4 of the first-second portion 191-1b may correspond to a thickness T4 obtained by subtracting the thickness T3 of the first-first portion 191-1a from the thickness T2 of the first-first region 191-1 of the first protective layer 190. In addition, a depth of the opening SOR1 formed in the first-second portion 191-1b may correspond to a thickness T4 of the first-second portion 191-1b.

At this time, a thickness T3 of the first-first portion 191-1a may range from 40% to 98% of the thickness T1 of the first pad 121. For example, the thickness T3 of the first-first portion 191-1a may range from 45% to 95% of the thickness T1 of the first pad 121. For example, the thickness T3 of the first-first portion 191-1a may range from 50% to 90% of the thickness T1 of the first pad 121.

At this time, an upper surface of the first-first portion 191-1a may have a curved surface or an inclined surface rather than a flat surface. In addition, when an upper surface of the first-first portion 191-1a has a flat or inclined surface, the thickness T3 of the first-first portion 191-1a may mean an average thickness of the first-first portion 191-1a.

If the thickness T3 of the first-first portion 191-1a is less than 40% of the thickness T1 of the first pad 121, the thickness T4 and the depth of the opening SOR1 of the first-second portion 191-1b increase, and accordingly, the horizontal distance of the recess portion UC formed at the side wall 191-1bs of the first-second portion 191-1b may increase. In addition, if the thickness T3 of the first-first portion 191-1a of the first-first region 191-1 is greater than 98% of the thickness T1 of the first pad 121, a problem may occur in which the first-first portion 191-1a covers the upper surface of the first pad 121 due to process deviation in a process of forming the opening SOR1, as a result, a circuit disconnection problem may occur as the upper surface of the first pad 121 is not completely exposed.

The first-first portion 191-1a of the first protective layer 190 may contact the upper surface of the first insulating layer 111. Additionally, the first-first portion 191-1a of the first protective layer 190 may cover a portion of the side surface of the first pad 121 and a portion of the side surface of the trace 124. Additionally, the first-first portion 191-1a of the first protective layer 190 may expose the remaining portion of the side surface of the first pad 121 and the remaining portion of the side surface of the trace 124.

The first-second portion 191-1b may be disposed on the first-first portion 191-1a and the trace 124 at a certain distance W3 from the first pad 121. For example, a side wall 191-1bs of the first-second portion 191-1b may be spaced apart from the first pad 121 by the distance W3. Accordingly, the upper surface of the first-first portion 191-a of the first protective layer 190 adjacent to the first pad 121 may be exposed corresponding to the distance W3.

Meanwhile, a recess portion UC may be provided at the side wall 191-1bs of the first-second portion 191-1b. For example, the recess portion UC may be formed between an upper surface of the first-first portion 191-1a and the side wall 191-1bs of the first-second portion 191-1b connected to the upper surface of the first-first portion 191-1a. For example, the recess portion UC may be formed in a step portion between the side walls 191-1bs of the first-first portion 191-1a and the first-second portion 191-1b.

A width of the recess portion UC may have a value greater than 0. At this time, etching according to the development is performed only in the first-second portion 191-1b excluding the first-first portion 191-1a, not the entire thickness of the first protective layer 190, and accordingly, the embodiment can reduce the horizontal distance W1 of the recess portion UC. The horizontal distance W1 of the recess portion UC may refer to a horizontal distance from an innermost end of the recess portion UC to an outermost end of the side wall 191-1bs of the first-second portion 191-1b.

A horizontal distance W1 of the recess portion UC may be 13 μm or less. For example, a horizontal distance W1 of the recess portion UC in the embodiment may be 10 μm or less. For example, a horizontal distance W1 of the recess portion UC in the embodiment may be 6 μm or less. For example, a horizontal distance W1 of the recess portion UC in the embodiment may be 2 μm or less.

Accordingly, in the first-second portion 191-1b of the embodiment, a width W2 between an outermost end 124-1 of the trace 124 and the side wall 191-1bs can be reduced compared to the comparative example.

For example, in the comparative example, the horizontal distance of the recess portion had to be at least 40 μm or more, and accordingly, the width between the outermost end of the trace and the side wall had to be at least 45 μm or more.

In contrast, the embodiment allows the opening SOR1 of the first-first region 191-1 of the first protective layer 190 to be formed by opening only the first-second portion 191-1b, so that the horizontal distance W1 of the recess portion UC can be significantly reduced compared to the comparative example. Accordingly, in the embodiment, a width W2 of a shortest distance between the outermost end 124-1 of the trace 124 and the outermost end of the side wall 191-1bs of the opening of the first-second portion 191-1b may have a range between 1 μm and 30 μm (e.g., greater than 1 um and less than 30 um). For example, in the embodiment, a width W2 of a shortest distance between the outermost end 124-1 of the trace 124 and the outermost end of the side wall 191-1bs of the opening of the first-second portion 191-1b may have a range between 2 μm and 25 μm (e.g., 2 um or more and 25 um or less). For example, in the embodiment, a width W2 of a shortest distance between the outermost end 124-1 of the trace 124 and the outermost end of the side wall 191-1bs of the opening of the first-second portion 191-1b may have a range between 3 μm and 20 μm (e.g., 3 um or more and 20 um or less). For example, in the embodiment, a width W2 of a shortest distance between the outermost end 124-1 of the trace 124 and the outermost end of the side wall 191-1bs of the opening of the first-second portion 191-1b may have a range between 5 μm and 18 μm (e.g., 5 um or more and 18 um or less). For example, in the embodiment, a width W2 of a shortest distance between the outermost end 124-1 of the trace 124 and the outermost end of the side wall 191-1bs of the opening of the first-second portion 191-1b may have a range between 7 μm and 16 μm (e.g., 7 um or more and 16 um or less).

If the width W2 of a shortest distance between the outermost end 124-1 of the trace 124 and the outermost end of the side wall 191-1bs of the opening of the first-second portion 191-1b is 1um or less, a portion of the outermost end of the trace 124 may be exposed by the recess portion, and electrical reliability problems such as circuit short may occur as a result. In addition, the width W2 of a shortest distance between the outermost end 124-1 of the trace 124 and the outermost end of the side wall 191-1bs of the opening of the first-second portion 191-1b exceeds 30 um, a spacing between the first pad and the trace increases, and thus the circuit integration degree of the circuit board decreases, and a width of the circuit board in the horizontal direction may increase.

Accordingly, in the embodiment, a separation distance W4 of a shortest distance between the first pad 121 and the trace 124 can be significantly reduced compared to the comparative example. For example, even if the separation distance W3 between the side wall 191-1bs of the first-second portion 191-1b and the first pad 121 is 15 um, the same as in the comparative example, the shortest distance between the first pad 121 and the trace 124 W4 can be reduced to 45 μm or less, further to 30 μm or less, further to 27 um or less, further to 22 um or less, and further to 18 um or less.

Accordingly, if a planar area of the circuit board of the embodiment is at the same level as that of the comparative example, the degree of integration of the circuit pattern layer disposed on the circuit board can be increased, which has the effect of allowing more circuit patterns to be disposed compared to the comparative example. Additionally, if the number of circuit boards of the circuit board of the embodiment is the same as the number of circuit patterns of the comparative example, a spacing between the circuit pattern layers can be reduced due to a structure of the first protective layer 190 as described above, and thus a width of the circuit board in the horizontal direction can be reduced.

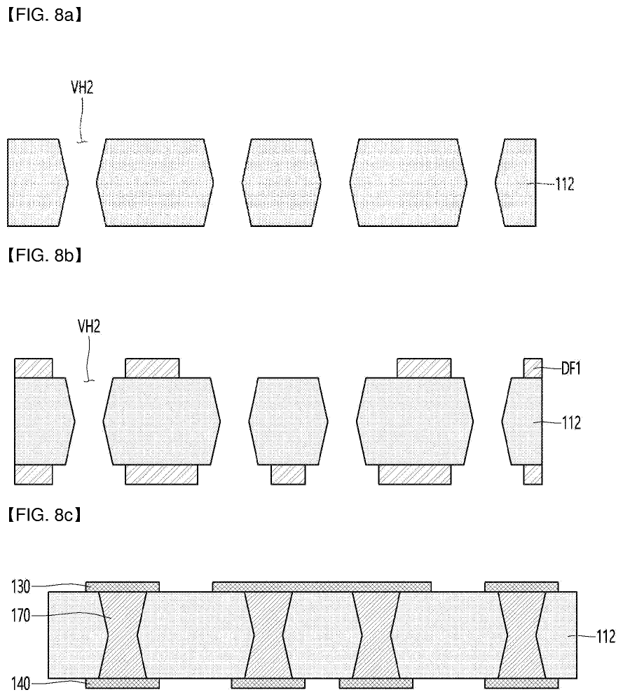

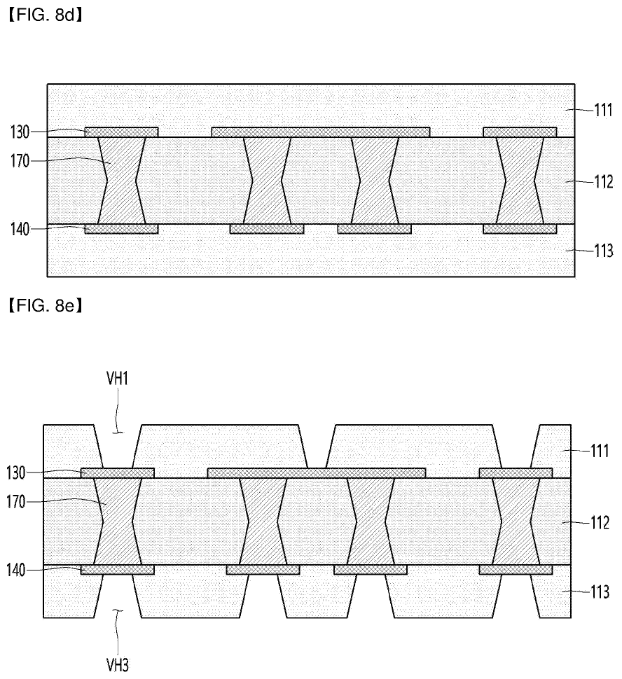

FIG. 6a is a view showing a first-second region of a first region of a first protective layer of FIG. 2a, and FIG. 6b is a view showing a SAM photograph of a circuit board corresponding to FIG. 6a. FIG. 6a is a cross-sectional view taken along line L2 in FIG. 2b.

Referring to FIGS. 6a and 6b, the first region 191 of the first protective layer 190 may be a region where a first opening SOR1 exposing the upper surface of the first pad 121 of the first circuit pattern layer 120 is formed. In addition, the first region 191 of the first protective layer 190 may be a region in which a portion of the first circuit pattern layer 120 adjacent to the first pad 121 is disposed. For example, the first region 191 of the first protective layer 190 may be a region in which the first pad 121 and the traces 124 of the first circuit pattern layer 120 adjacent to the first pad 121 are disposed. For example, the first region 191 of the first protective layer 190 may be a region in which the first pad 121 and a third pad 123 adjacent to the first pad 121 are disposed.

Accordingly, the first region 191 of the first protective layer 190 may include a first-first region 191-1 between the first pad 121 and the trace 124, and a first-second region 191-2 between the first pad 121 and the third pad 123. And, FIG. 6a may show the first-second region 191-2 in the first region 191.

In addition, the first-second region 191-2 of the first protective layer 190 includes a second-first portion 191-2a disposed between the first pad 121 and the third pad 123 of the first circuit pattern layer 120. The second-first portion 191-2a may also be referred to as a first portion of the first region 191 of the first protective layer 190.

In addition, the first-second region 191-2 of the first protective layer 190 may include a second-second portion 191-2b including a first opening SOR1 and a second opening SOR2. And, the first opening SOR 1 covers a portion of the upper surface of the third pad 123 on the second-first portion 191-2a and exposes the upper surface of the first pad 121, and the second opening SOR 2 exposes the upper surface of the third pad 123. The second-second portion 191-2b may also be referred to as the second portion of the first region 191 of the first protective layer 190 disposed on the second-first portion 191-2a.

Here, the thickness T1 of the third pad 123, the thickness T2 of the first-second region 191-2 of the first protective layer 190, the thickness T3 of the second-first portion 191-2a, and the second-second portion 191-2b have already been described in the first-first region 191-1, detailed description thereof will be omitted.

Meanwhile, the second-second portion 191-2b includes a first side wall 191-2bs1 corresponding to the first opening SOR1 and a second side wall 191-2bs2 corresponding to the second opening SOR2.

Additionally, a first recess portion UC1 may be formed at the first side wall 191-2bs1, and a second recess portion UC2 may be formed at the second side wall 191-2bs2.

At this time, a horizontal distance W1 of the first recess portion UC1 may be 13 μm or less. For example, in the embodiment, a horizontal distance W1 of the first recess portion UC1 may be 10 μm or less. For example, in the embodiment, a horizontal distance W1 of the first recess portion UC1 may be 6 μm or less. For example, in the embodiment, a horizontal distance W1 of the first recess portion UC1 may be 2 μm or less.

Accordingly, the second-second portion 191-2b in the embodiment can reduce the width W2 between the outermost end 123-1 of the third pad 123 and the first side wall 191-2bs1 compared to the comparative example.

For example, the embodiment allows the first opening SOR1 of the first-second region 191-2 of the first protective layer 190 to be formed by opening only the second-second portion 191-2b, so that the horizontal distance W1 of the first recess portion UC1 can be significantly reduced compared to the comparative example. Accordingly, in the embodiment, the width W2 of the shortest distance between the outermost end of the first side wall 191-2bs1 of the second-second portion 191-2b and the outermost end 123-1 of the third pad 123 may range between 1 μm and 30 μm (e.g., greater than 1 μm, less than or equal to 30 μm). For example, in the embodiment, the width W2 of the shortest distance between the outermost end of the first side wall 191-2bs1 of the second-second portion 191-2b and the outermost end 123-1 of the third pad 123 may range between 2 μm and 25 μm (e.g., 2 um or more and 25 um or less). For example, in the embodiment, the width W2 of the shortest distance between the outermost end of the first side wall 191-2bs1 of the second-second portion 191-2b and the outermost end 123-1 of the third pad 123 may range between 3 μm and 20 μm (e.g., 3 um or more and 20 um or less). For example, in the embodiment, the width W2 of the shortest distance between the outermost end of the first side wall 191-2bs1 of the second-second portion 191-2b and the outermost end 123-1 of the third pad 123 may range between 5 μm and 18 μm (e.g., 5 um or more and 18 um or less). For example, in the embodiment, the width W2 of the shortest distance between the outermost end of the first side wall 191-2bs1 of the second-second portion 191-2b and the outermost end 123-1 of the third pad 123 may range between 7 μm and 16 μm (e.g., 7 um or more and 16 um or less).

Accordingly, the embodiment can significantly reduce a separation distance of the shortest distance W4 between the first pad 121 and the third pad 123 compared to the comparative example. For example, even if the separation distance W3 between the first side wall 191-2bs1 of the second-second portion 191-2b and the first pad 121 is at the same level of 15 um as in the comparative example, the separation distance W4 of the shortest distance between the first pad 121 and the third pad 123 can be reduced to 45 um or less, further to 30 um or less, further to 27 um or less, further to 22 um or less, and further to 18 um or less.

Meanwhile, a second recess portion UC2 may be formed at the second side wall 191-2bs2 of the second-second portion 191-2b.

At this time, a position where the second recess portion UC2 is formed is higher than a position where the first recess portion UC1 is formed. That is, the first recess portion UC1 is formed at a height lower than the height of the upper surface of the third pad 123. In contrast, the second recess portion UC2 is formed at a height equal to or higher than the height of the upper surface of the third pad 123. Accordingly, the horizontal distance W1-1 of the second recess portion UC2 may be smaller than the horizontal distance of the first recess portion UC1.

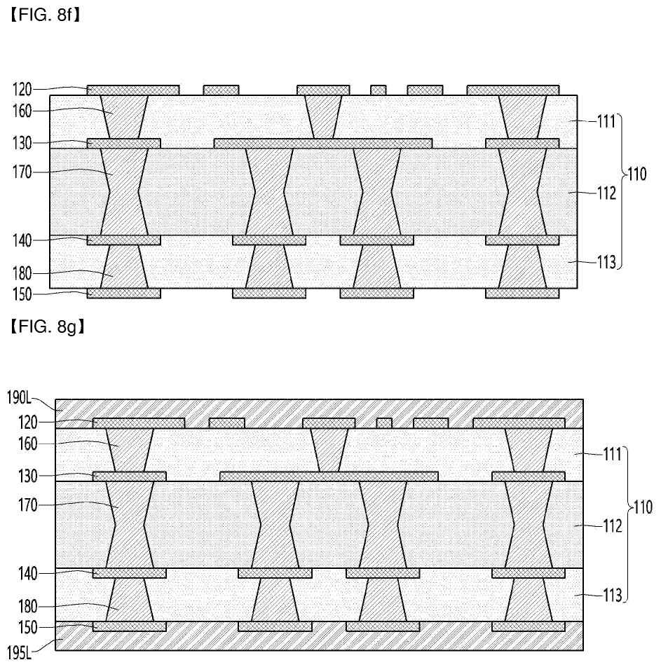

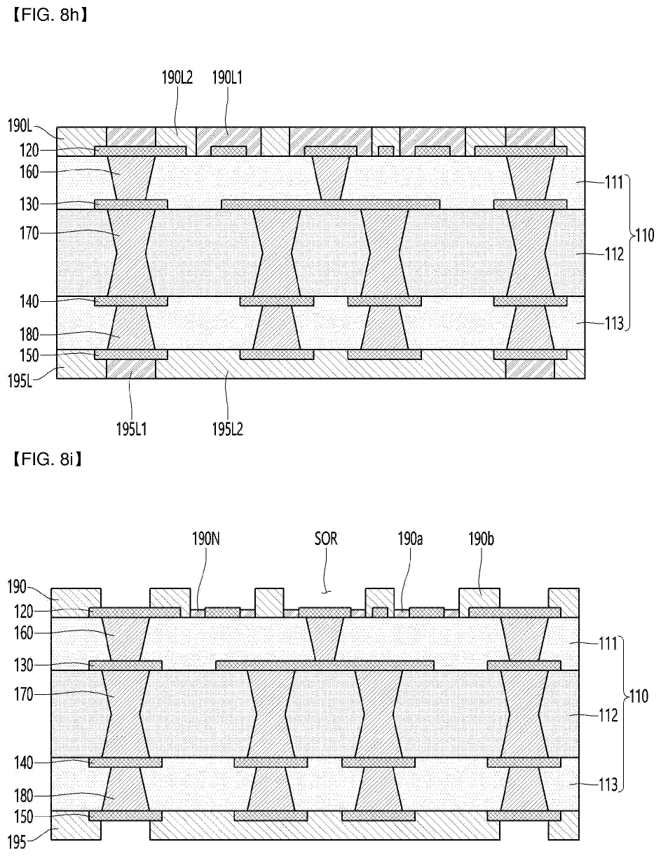

FIG. 7a is a view showing a second region of a first protective layer of FIG. 2a, and FIG. 7b is a view showing a SAM photograph of a circuit board corresponding to FIG. 7a. FIG. 7a is a cross-sectional view taken along line L3 in FIG. 2b.

Referring to FIGS. 7a and 7b, the second region 192 of the first protective layer 190 may be a region where an opening exposing the upper surface of the second pad 122 of the first circuit pattern layer 120 is formed. For example, the second region 192 of the first protective layer 190 may be disposed between the plurality of second pads 122. For example, the second region 192 of the first protective layer 190 may be a region in which the first circuit pattern layer 120 is not disposed among the regions between the plurality of second pads 122. The second region 192 of the first protective layer 190 may function as a dam to partition a region between the plurality of second pads 122.

For example, the second region 192 of the first protective layer 190 may be disposed between the second-first pad 122-1 and the second-second pad 122-2.

The second region 192 of the first protective layer 190 includes a first portion 192-1 of the second region 192 disposed on an upper surface of the first insulating layer 111 between the second-first pad 121 and the second-second pad 122-2.

Additionally, the second region 192 may include a second portion 192-2 of the second region 192 disposed on the first portion 192-1 of the second region 192. A width of the second portion 192-2 of the second region 192 may be smaller than A width of the first portion 192-1 of the second region 192. Accordingly, a portion of the upper surface of the first portion 192-1 of the second region 192 may be exposed.

One end of the first portion 192-1 of the second region 192 may contact a side surface of the second-first pad 122-1. Additionally, the other end of the first portion 192-1 of the second region 192 may contact a side surface of the second-second pad 122-2.

A thickness T3 of the first portion 192-1 of the second region 192 may range from 40% to 98% of the thickness T1 of the second-first pad 122-1 and the second-second pad 122-2. For example, a thickness T3 of the first portion 192-1 of the second region 192 may range from 45% to 95% of the thickness T1 of the second-first pad 122-1 and the second-second pad 122-2. For example, a thickness T3 of the first portion 192-1 of the second region 192 may range from 50% to 90% of the thickness T1 of the second-first pad 122-1 and the second-second pad 122-2.

At this time, the upper surface of the first portion 192-1 of the second region 192 may have a curved or inclined surface rather than a flat surface. And, when the upper surface of the first portion 192-1 of the second region 192 has a flat or inclined surface, the thickness T3 of the first portion 192-1 of the second region 192 may mean an average thickness of the first portion 192-1 of the second region 192.

If the thickness T3 of the first portion 192-1 of the second region 192 is less than 40% of the thickness T1 of the second-first pad 122-1 and the second-second pad 122-2, a horizontal distance of the recess portion formed at the side wall of the second portion 192-2 of the second region 192 may increase. If the thickness T3 of the first portion 192-1 of the second region 192 is greater than 98% of the thickness T1 of the second-first pad 122-1 and the second-second pad 122-2, a circuit disconnection problem may occur as the upper surfaces of the second-first pad 122-1 and the second-second pad 122-2 are not completely exposed due to process deviation in the process of forming the opening.

The second portion 192-2 of the second region 192 includes a first side wall 192-21 corresponding to an opening that exposes an upper surface of the second-first pad 122-1 and a portion of the side surface of the second-first pad 122-1.

The second portion 192-2 of the second region 192 includes a second side wall 192-22 corresponding to an opening that exposes an upper surface of the second- second pad 122-2 and a portion of the side surface of the second-second pad 122-2.

In addition, a first recess portion U1 is formed at the first side wall 192-21 of the second portion 192-2 of the second region 192, and a second recess portion U2 may be formed at the second side wall 192-22.

At this time, a horizontal distance W1 of the first recess portion U1 and the second recess portion U2 may be 13 μm or less. For example, in the embodiment, a horizontal distance W1 of the first recess portion U1 and the second recess portion U2 may be 10 μm or less. For example, a horizontal distance W1 of the first recess portion U1 and the second recess portion U2 may be 6 μm or less. For example, a horizontal distance W1 of the first recess portion U1 and the second recess portion U2 may be 2 μm or less.

Accordingly, the width W5 of the second portion 192-2 of the second region 192 in the embodiment can be reduced compared to the comparative example.

For example, the embodiment allows the opening of the second region 192 of the first protective layer 190 to be formed by opening only the second portion 192-2, so that the horizontal distance between the first recess portion U1 and the second recess portion U2 can be reduced compared to the comparative example.

For example, in the comparative example, the width of the first protective layer in the second region was 90 μm or more. In contrast, in the embodiment, the width W5 of the second portion 192-2 of the second region 192 of the first protective layer 190 may be 40 μm or less. In an embodiment, the width W5 of the second portion 192-2 of the second region 192 of the first protective layer 190 may be 30 μm or less. In an embodiment, the width W5 of the second portion 192-2 of the second region 192 of the first protective layer 190 may be 20 μm or less. In an embodiment, the width W5 of the second portion 192-2 of the second region 192 of the first protective layer 190 may be 10 μm or less. In an embodiment, the width W5 of the second portion 192-2 of the second region 192 of the first protective layer 190 may be 5 μm or less.

Accordingly, in the embodiment, a separation distance W6 between the second-first pad 122-1 and the second-second pad 122-2 can be significantly reduced compared to the comparative example. For example, even if the separation distance W3 between the first side wall 192-21 of the second portion 192-2 of the second region 192 and the second-first pad 122-1, and the separation distance W3 between the second side wall 192-22 and the second-second pad 122-2 is at the same level of 15um as in the comparative example, a separation distance W6 of the shortest distance between the second-first pad 122-1 and the second-second pad 122-2 can be reduced to 70 um or less, further to 60 um or less, further to 50 μm or less, and further to 35 μm or less.

A circuit board according to an embodiment includes a first protective layer. The first protective layer includes a first portion and a second portion having steps. And, in an embodiment, an opening formed in the first protective layer may be formed by selectively removing only the second portion excluding the first portion. At this time, a thickness of the first portion of the first protective layer is smaller than a thickness of the first circuit pattern layer exposed through the opening. Accordingly, the opening formed in the second portion of the first protective layer may expose a portion of a side surface of the first circuit pattern layer and an upper surface of the first circuit pattern layer. Accordingly, the embodiment allows the opening to have a depth corresponding to the thickness of the second portion rather than a depth corresponding to an entire thickness of the first protective layer. Accordingly, the embodiment can allow to significantly reduce a horizontal distance of a recess portion corresponding to an undercut formed at the side wall of the opening compared to the comparative example. Accordingly, the embodiment can reduce the horizontal distance of the recess portion, thereby improving the electrical reliability or physical reliability of the circuit board. For example, when the horizontal distance of the recess portion increases, a portion of the solder ball may penetrate between the recess portions, and short circuit problems may occur as neighboring circuit patterns are connected. For example, when the horizontal distance of the recess portion increases, an contact area between the first protective layer and the insulating layer decreases, and an adhesion force between the first protective layer and the insulating layer may be reduced. In contrast, the embodiment can reduce the horizontal distance of the recess portion, and accordingly, electrical reliability problems such as the short circuit can be solved, and furthermore, physical reliability problems such as the decrease in bonding force can be solved.

In addition, the embodiment allows the thickness of the first portion of the first protective layer to range from 40% to 98% of the first circuit pattern layer. Accordingly, the embodiment can dramatically reduce the horizontal distance of the recess portion while allowing the upper surface of the first circuit pattern layer to be stably exposed through an opening formed in the second portion.

In addition, the embodiment may reduce the horizontal distance of the recess portion to reduce a spacing between pads of the first circuit pattern layer, between a pad and a trace, or between traces. Specifically, the spacing between pads of the first circuit pattern layer or between a pad and a trace or between traces is determined by reflecting the horizontal distance of the recess portion to solve the electrical reliability problem. At this time, the embodiment may reduce the horizontal distance of the recess portion, and accordingly, the distance between the pads of the first circuit pattern layer, or between the pad and the trace, or between the traces, which is determined by the horizontal distance of the recess portion, can be dramatically reduced.

Hereinafter, a method of manufacturing a circuit board according to an embodiment will be described.

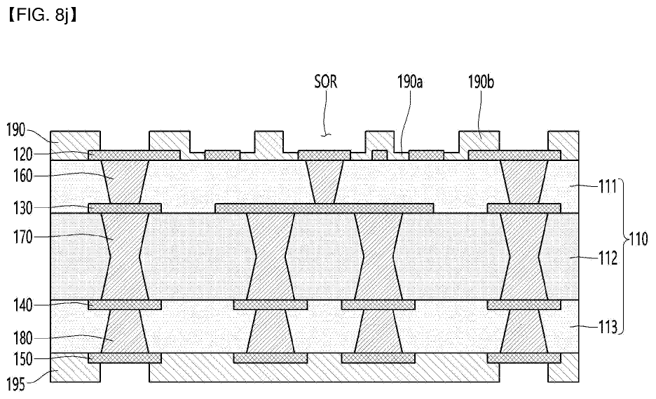

FIGS. 8a to 8j are diagrams for explaining a method for manufacturing a circuit board of FIG. 2a in order of process.

Referring to FIG. 8a, in the embodiment, a second insulating layer 112 is prepared. The second insulating layer 112 may be a core layer. Accordingly, the second insulating layer 112 may be CCL (Copper Clad Laminate). In addition, the embodiment may proceed with a process of forming a second via hole VH2 penetrating the second insulating layer 112. At this time, the second insulating layer 112 is a core layer having a certain thickness or more, and accordingly, the process of forming the second via hole VH2 includes a first process of forming a first part of the second via hole VH2 at an upper side of the second insulating layer 112 and a second process of forming a second part connected to the first part of the second via hole VH2 at a lower side of the second insulating layer 112. Accordingly, the second via hole VH2 may have an hourglass shape based on the combination of the first part and the second part. Meanwhile, although not shown in FIG. 8a, copper foil layers (not shown) may be laminated on the upper and lower surfaces of the second insulating layer 112, respectively.

Next, the embodiment may proceed with a process of forming the second via 170 to fill the second via hole VH2 of the second insulating layer 112, a process of forming a second circuit pattern layer 130 disposed on the upper surface of the second insulating layer 112, and a process of forming a third circuit pattern layer 140 disposed on the lower surface of the second insulating layer 112.

To this end, as shown in FIG. 8b, the embodiment may proceed with a process of forming a dry film DF1 with an opening exposing the region where the second circuit pattern layer 130 and the third circuit pattern layer 140 will be formed on the upper and lower surfaces of the second insulating layer 112, respectively.

In addition, as shown in FIG. 8c, the embodiment may proceed with a plating process to fill the opening of the second via hole VH2 and the dry film DF1, so that the second via 170, the second circuit pattern layer 130, and the third circuit pattern layer 140 may be formed. At this time, the plating may be performed using the chemical copper plating layer as a seed layer, after performing electroless plating on the second insulating layer 112 or the copper foil layer (not shown) to form a chemical copper plating layer (not shown).

Next, as shown in FIG. 8d, the embodiment may proceed with a process of laminating the first insulating layer 111 on the first or upper surface of the second insulating layer 112 and a process of laminating the third insulating layer 113 on the second or lower surface of the second insulating layer 112.

At this time, the first insulating layer 111 and the third insulating layer 113 may be prepreg or, alternatively, may be RCC.

In addition, although not shown in the drawing, a copper foil layer (not shown) may be formed on the first surface of the first insulating layer 111 and the second surface of the third insulating layer 113, respectively.

Next, the embodiment may proceed with a process of forming via holes VH1 and VH3 in the first insulating layer 111 and the third insulating layer 113.

Next, as shown in FIG. 8f, the embodiment may proceed with a plating process of forming a first via 160 and a third via 180 to fill the via holes VH1 and VH3, a plating process of forming a first circuit pattern layer 120 on the upper surface of the first insulating layer 111, and a plating process for forming a fourth circuit pattern layer 150 on the lower surface of the third insulating layer 113.

Next, as shown in FIG. 8g, the embodiment may proceed with a process of forming a first solder resist layer 190L on the upper surface of the first insulating layer 111 and a process of forming a second solder resist layer 195L on the lower surface of the third insulating layer 113. At this time, the first solder resist layer 190L and the second solder resist layer 195L may be formed entirely on an upper part of the first insulating layer 111 and a lower part of the third insulating layer 113.

Next, as shown in FIG. 8h, the embodiment may proceed with a process of exposing the first solder resist layer 190L and the second solder resist layer 195L, respectively.

For example, the embodiment may proceed with a process of exposing the remaining region 190L2 of the first solder resist layer 190L excluding the region 190L1 where the opening is to be formed. Additionally, the embodiment may proceed with a process of exposing the remaining region 195L2 of the second solder resist layer 195L excluding the region 195L1 where the opening is to be formed.

Thereafter, the embodiment may proceed with a process of curing the remaining regions 190L2 and 195L2 that have been exposed through the exposure process. However, the curing process may not be performed separately but may be performed together with the exposure process.

Next, in the embodiment, as shown in FIG. 8i, the embodiment may proceed with a process of forming an opening by developing the uncured regions 190L1 and 195L1 excluding the cured regions 190L2 and 195L2.

At this time, in the embodiment, a process of reducing the thickness of the uncured regions 190L1 and 195L1 may be performed by thinning the uncured regions 190L1 and 195L1 to form the opening. At this time, the thinning may be performed on the unexposed region using an organic alkaline compound containing tetramethylammonium hydroxide (TMAH) or trimethyl-2-hydroxyethylammonium hydroxide (choline), etc.

Accordingly, the embodiment controls a thickness of the uncured region 190L1 of the first solder resist layer 190L in the thinning process, and thereby, it is possible to allow only a portion of the uncured region 190L1 to be removed without removing the entirety.

Accordingly, the first solder resist layer 190L can be divided into a first portion 190a having a thickness smaller than that of the first circuit pattern layer 120, and a second portion 190b having an opening SOR on the first portion 190a. Specifically, the embodiment may proceed with a thinning process to have shapes corresponding to the first region 191 and the second region 192 shown in FIGS. 5a, 6a, and 7a.

Hereafter, the embodiment may proceed with a process of curing the region 190N (specifically the first portion 190a exposed through the opening SOR) that was not removed in the thinning process among the uncured regions 190L1.

And, the embodiment may form the first protective layer 190 and the second protective layer 195 through the above process.

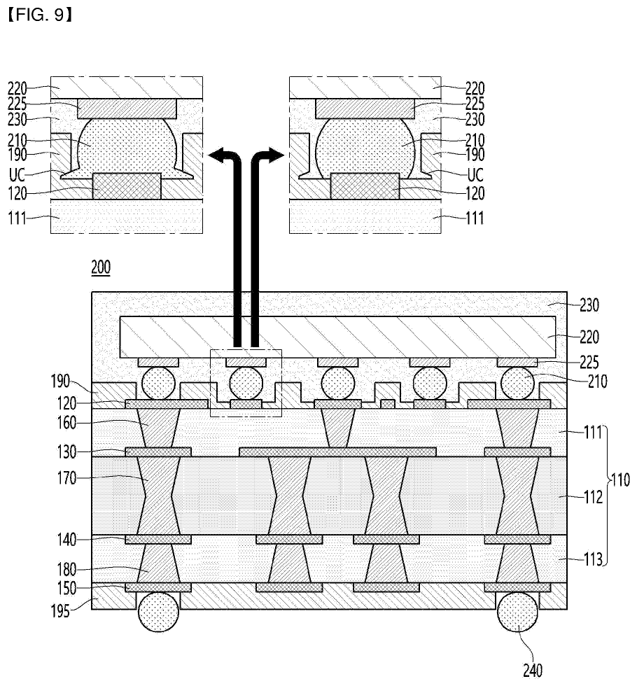

FIG. 9 is a view showing a package substrate according to a first embodiment.

A package substrate of the first embodiment may have a structure in which at least one chip is mounted on the circuit board of FIG. 2a.

For example, the package substrate may include a connection part 210 disposed on the pads 121, 122, and 123 of the first circuit pattern layer 120 disposed on the first outermost side of the circuit board.

The connection part 210 may have a spherical shape. For example, a cross section of the connection part 210 may include a circular shape or a semicircular shape. For example, a cross section of the connection part 210 may include a partially or entirely rounded shape. A cross-sectional shape of the connection part 210 may be flat at one side surface and curved at the other side surface. The connection part 210 may be a solder ball, but is not limited thereto.

Alternatively, the connection part 210 may have a hexahedral shape. For example, a cross section of the connection part 210 may have a rectangular shape. A cross section of the connection part 210 may include a rectangle or square.

Meanwhile, the connection part 210 may fill at least a portion of the recess portion formed in the first protective layer 190 of the circuit board. For example, at least a portion of the connection portion 210 may penetrate into the recess portion formed in the first protective layer 190 during a reflow process.

The package substrate of the embodiment may include a chip 220 disposed on the connection part 210. The chip 220 may be a processor chip. For example, the chip 220 may be an application processor (AP) chip of any one of a central processor (e.g., CPU), a graphics processor (e.g., GPU), a digital signal processor, a cryptographic processor, a microprocessor, a and microcontroller.

At this time, a terminal 225 may be provided at the lower surface of the chip 220, and the terminal 225 may be electrically connected to the pads 121, 122, and 123 of the first circuit pattern layer 120 of the circuit board through the connection portion 210.

Meanwhile, the package substrate of the embodiment may allow a plurality of chips to be arranged at a certain distance from each other on one circuit board. For example, the chip 220 may include a first chip and a second chip that are spaced apart from each other.

Also, the first chip and the second chip may be different types of application processor (AP) chips.

Meanwhile, the first chip and the second chip may be spaced apart from each other at a certain distance on the circuit board. For example, the distance between the first chip and the second chip may be 150 μm or less. For example, the distance between the first chip and the second chip may be 120 μm or less. For example, the distance between the first chip and the second chip may be 100 μm or less.

Preferably, for example, the distance between the first chip and the second chip may range from 60 μm to 150 μm. For example, the distance between the first chip and the second chip may range from 70 μm to 120 μm. For example, the distance between the first chip and the second chip may range from 80 μm to 110 μm. For example, if the distance between the first chip and the second chip is less than 60 um, mutual interference may occur between the first chip and the second chip, and this may cause problems with the operational reliability of the first chip or the second chip. For example, if the distance between the first chip and the second chip is greater than 150 um, signal transmission loss may increase as the distance between the first chip and the second chip increases.

The package substrate may include a molding layer 230. The molding layer 230 may be disposed to cover the chip 220. For example, the molding layer 230 may be EMC (Epoxy Mold Compound) formed to protect the mounted chip 220, but is not limited thereto.

Meanwhile, at least one recess portion UC is formed in the protective layer 190 of the circuit board. And, the recess portion UC in the first embodiment may be filled with the connection part 210 or the molding layer 230.

For example, as shown in the first enlarged view of FIG. 9, the recess portion UC may be filled by the connection part 210. That is, a reflow process of the connection part 210 may be performed during the process of mounting the chip 220 on the connection part 210. Additionally, the connection part 210 may spread during the reflow process, and accordingly, the recess portion UC may be filled by the connection part 210.

For example, as shown in the second enlarged view of FIG. 9, the connection part 210 may not spread to the recess portion UC during the reflow process of the connection part 210. At this time, the recess portion UC may be filled with the molding layer 230.

At this time, the molding layer 230 may have a low dielectric constant to increase heat dissipation characteristics. For example, the dielectric constant (Dk) of the molding layer 230 may be 0.2 to 10. For example, the dielectric constant (Dk) of the molding layer 230 may be 0.5 to 8. For example, the dielectric constant (Dk) of the molding layer 230 may be 0.8 to 5. Accordingly, in the embodiment, the molding layer 230 has a low dielectric constant to improve heat dissipation characteristics for heat generated from the chip 220.

Meanwhile, the package substrate may include a solder ball 240 disposed on a lowermost side of the circuit board. The solder ball 240 may be used for bonding between the package substrate and an external substrate (e.g., a main board of an external device).

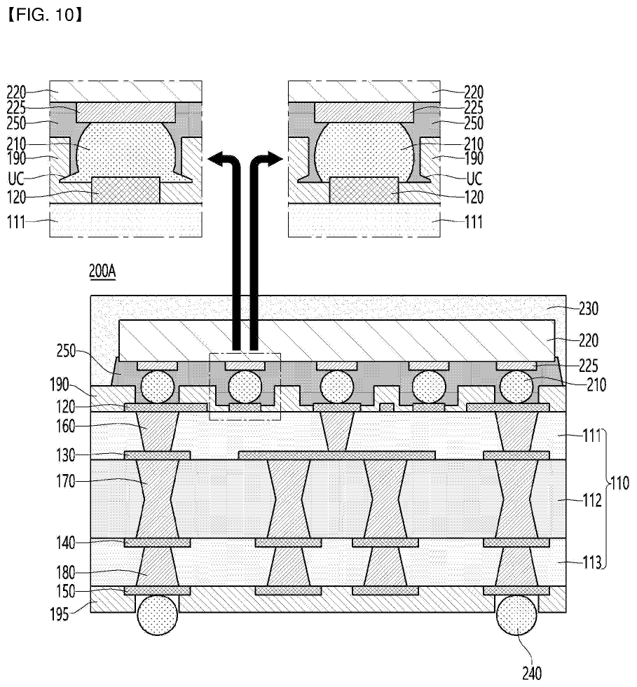

FIG. 10 is a view showing the package substrate according to a second embodiment.

A package substrate according to a second embodiment of FIG. 10 is substantially the same as that of FIG. 9, but there may be a difference in that a fillet layer 250 is additionally disposed within the molding layer 230.

A fillet layer 250 may be formed on a circuit board to surround the connection part 210 and the terminal 225 of the chip 220. The fillet layer 250 may be additionally formed to prevent foreign substances (e.g., moisture, etc.) from penetrating into the space between the circuit board and the chip 220 after the chip 220 is mounted.

In addition, when the fillet layer 250 is included, the recess portion UC of the protective layer of the circuit board may be filled by the connection portion 210 as shown in the first and second enlarged views of FIG. 10, or alternatively, the recess portion UC of the protective layer of the circuit board may be filled with the fillet layer 250.

The characteristics, structures, effects, and the like described in the above-described embodiments are included in at least one embodiment, but are not limited to only one embodiment. Furthermore, the characteristic, structure, and effect illustrated in each embodiment may be combined or modified for other embodiments by a person skilled in the art. Therefore, it should be construed that contents related to such combination and modification are included in the scope of the embodiment.

1. A circuit board comprising:
a first insulating layer;
a first circuit pattern layer disposed on the first insulating layer; and
a first protective layer disposed on the first insulating layer and the first circuit pattern layer,
wherein the first circuit pattern layer includes a first pad,
wherein the first protective layer is divided into a first portion disposed on the first insulating layer in a thickness direction and a second portion disposed on the first portion,
wherein the second portion of the first protective layer includes an opening with a width greater than a width of the first pad, and
wherein a side wall of the second portion forming the opening is provided with a recess portion recessed in an inward direction.

2. The circuit board of claim 1, wherein a horizontal distance from an outermost end of the side wall of the second portion to an innermost end of the recess portion is 13 μm or less.

3. The circuit board of claim 1, wherein a thickness of the first portion of the first protective layer is smaller than a thickness of the first pad.

4. The circuit board of claim 3, wherein the thickness of the first portion of the first protective layer satisfies a range of 40% to 98% of the thickness of the first pad.

5. The circuit board of claim 1, wherein the recess portion is provided at a step portion between an upper surface of the first portion exposed through the opening and a side wall of the opening of the second portion connected to the upper surface of the first portion.

6. The circuit board of claim 1, wherein an upper surface of the first portion of the first protective layer is positioned lower than an upper surface of the first pad, and
wherein an upper surface of the second portion of the first protective layer is positioned higher than the upper surface of the first pad.

7. The circuit board of claim 1, wherein the first circuit pattern layer includes a trace disposed adjacent to the first pad and covered by the second portion of the first protective layer; and
wherein a shortest horizontal distance between a side surface of the trace and an outermost end of the side wall of the second portion satisfies a range of 1 um to 30 um.

8. A circuit board comprising:
a first insulating layer;
a first circuit pattern layer disposed on the first insulating layer; and
a first protective layer disposed on the first insulating layer and the first circuit pattern layer,
wherein the first circuit pattern layer includes a first pad and an adjacent pattern adjacent to the first pad,
wherein the first protective layer includes a first portion of a first region disposed between the first pad and the adjacent pattern and a second portion of the first region disposed on the first portion of the first region to cover the adjacent pattern and having a first opening exposing a portion of an upper surface of the first portion of the first region and the upper surface of the first pad, and
wherein the second portion of the first region includes a first side wall corresponding to the first opening,
wherein a horizontal distance between the first sidewall from a side surface of the adiacent pattern varies along a vertical direction, and
wherein a shortest horizontal distance between a side surface of the adjacent pattern and the first sidewall is 30 μm or less.

9. The circuit board of claim 8, wherein the adjacent pattern is a trace disposed adjacent to the first pad.

10. The circuit board of claim 9, wherein a recess portion recessed in the inward direction is provided at the first side wall of the second portion, and wherein a horizontal distance from an outermost end of the first side wall of the second portion to an innermost end of the recess portion is 13 μm or less.

11. The circuit board of claim 8, wherein the adjacent pattern is a third pad disposed adjacent to the first pad.

12. The circuit board of claim 11, wherein the second portion further includes a second opening exposing a portion of an upper surface of the third pad.

13. The circuit board of claim 11, wherein the first side wall of the second portion is provided with a first recess portion recessed in an inward direction.

14. The circuit board of claim 12, wherein the second portion includes a second side wall corresponding to the second opening, and
wherein the side wall of the second portion is provided with a second recess portion recessed in an inward direction.

15. The circuit board of claim 11, wherein the second portion includes a second opening exposing a portion of an upper surface of the third pad,
wherein the first side wall of the second portion is provided with a first recess portion recessed in an inward direction,
wherein the second portion includes a second side wall corresponding to the second opening,
wherein the second side wall of the second portion is provided with a second recess portion recessed in an inward direction, and
wherein a horizontal distance from an innermost end of the first recess portion to an outermost end of the first side wall is greater than a horizontal distance from an innermost end of the second recess portion to an outermost end of the second side wall.

16. The circuit board of claim 15, wherein the horizontal distance from the innermost end of the first recess portion to the outermost end of the first side wall is 13 μm or less.

17. The circuit board of claim 8, wherein the first circuit pattern layer includes a second-first pad and a second-second pad,
wherein the first protective layer includes:
a first portion of a second region disposed in a region between the second-first pad and the second-second pad where the first circuit pattern layer is not disposed, and
a second portion of the second region disposed on the first portion of the second region and exposing a portion of an upper surface of the first portion of the second region; and
wherein a width of the second portion of the second region is 40 μm or less.

18. The circuit board of claim 8, wherein a thickness of the first portion of the first region satisfies a range of 40% to 98% of a thickness of the first pad.

19. A semiconductor package comprising:
a first insulating layer;
a first circuit pattern layer disposed on the first insulating layer; and
a first protective layer disposed on the first insulating layer and the first circuit pattern layer and having an opening overlapping the first circuit pattern layer along a vertical direction;
a connection part disposed in the opening of the first protective layer;
a chip disposed on the connection part; and
a molding layer for molding the chip,
wherein the first protective layer includes:
a first portion disposed on the first insulating layer;
a second portion disposed on the first portion and having an opening exposing a portion of an upper surface of the first portion and an upper surface of the first circuit pattern layer,
wherein a side wall of the second portion is provided with a recess portion recessed in an inward direction, and
wherein at least one of the connection part and the molding layer is provided to fill the recess portion.

20. The semiconductor package of claim 19, wherein the chip includes a first chip and a second chip spaced apart from each other in a width direction or disposed in a vertical direction.
